(19) United States
(12) Patent Application Publication
(10) Pub. No.: US 2024/0079841 A1
(43) Pub. Date: Mar. 7, 2024

(54) CIRCUITS AND METHODS FOR POLYPHASE CONTROL OF PUMP DIODES IN A FIBER LASER

(71) Applicant: Innovusion, Inc., Sunnyvale, CA (US)

(72) Inventor: Yimin Li, Cupertino, CA (US)

(73) Assignee: Innovusion, Inc., Sunnyvale, CA (US)

(21) Appl. No.: 18/242,456

(22) Filed: Sep. 5, 2023

Related U.S. Application Data
(60) Provisional application No. 63/404,098, filed on Sep. 6, 2022.

(51) Int. Cl. H01S 3/091; G01S 7/481; G01S 7/484; G01S 17/931; H01S 3/094

(52) U.S. Cl. CPC H01S 3/0912; G01S 7/4814; G01S 7/4818; G01S 7/484; G01S 17/931; H01S 3/094076; H01S 3/0941

(57) ABSTRACT

A light detection and ranging (LiDAR) system in which multiple pump lasers are operated in polyphase fashion at a single pumping stage is disclosed. In some embodiments, the multiple pump lasers are operated by controllers that generate current pulses through the multiple pump lasers. The current pulses powering at least two of the pumping lasers have different phases. In some embodiments, the phase differences are such that there is no timing overlap in the current pulses through the pump lasers. In some embodiments, the phase difference between successive current pulses is greater than the pulse width such that the sum of the duty cycles of all the current pulses is less than one. In some embodiments, junction temperatures of pump lasers are monitored and temperature information from the monitoring is used to dynamically select which pump laser will be utilized at a given time. Further details of these and other embodiments are disclosed herein.

### CROSS REFERENCE TO RELATED APPLICATIONS

This application claims priority to U.S. Provisional Application No. 63/404,098 filed on Sep. 6, 2022. The entire contents of that application are hereby incorporated herein by reference.

### FIELD OF THE TECHNOLOGY

This disclosure relates generally to a laser source and, more particularly, to an electronic device for facilitating a polyphase control of a plurality of laser pumps used in a light detection and ranging (LiDAR) system.

### BACKGROUND

Light detection and ranging (LiDAR) systems use light pulses to create an image or point cloud of the external environment. Some typical LiDAR systems include a light source, a light transmitter, a light steering system, and a light detector. The light source generates a light beam that is directed by the light steering system in particular directions when being transmitted from the LiDAR system. When a transmitted light beam is scattered by an object, a portion of the scattered light returns to the LiDAR system as a return light pulse. The light detector detects the return light pulse. Using the difference between the time that the return light pulse is detected and the time that a corresponding light pulse in the light beam is transmitted, the LiDAR system can determine the distance to the object using the speed of light. The light steering system can direct light beams along different paths to allow the LiDAR system to scan the surrounding environment and produce images or point clouds. LiDAR systems can also use techniques other than time-of-flight and scanning to measure the surrounding environment.

### SUMMARY

A LiDAR operating at the 1550 nm wavelength uses a fiber laser in a MOPA (Master Oscillator Power Amplifier) structure as a laser source. The present challenges with this type of fiber laser include a low WPE (wall plug efficiency) and a low pump diode reliability. One way to improve reliability is to add redundancy. In a fiber laser, for example, adding redundancy can be implemented by adding multiple pump diodes.

In embodiments of the present invention, multiple pump lasers are operated in polyphase fashion at a single pumping stage. In some embodiments, the multiple pump lasers are operated by controllers that generate current pulses through the multiple pump lasers. The current pulses powering at least two of the pumping lasers have different phases. In some embodiments, the phase differences are such that there is no timing overlap in the current pulses through the pump lasers. In some embodiments, the phase difference between successive current pulses is greater than the pulse width such that the sum of the duty cycles of all the current pulses is less than one.

In other embodiments, junction temperatures are monitored for each of a plurality of pump lasers diodes and a selection of which pump lasers to use at a present time is made based on the results of monitoring.

These and other embodiments are illustrated and described further herein.

### BRIEF DESCRIPTION OF THE DRAWINGS

The present application can be best understood by reference to the figures described below taken in conjunction with the accompanying drawing figures, in which like parts may be referred to by like numerals.

FIG. 1 illustrates one or more exemplary LiDAR systems disposed or included in a motor vehicle.

FIG. 2 is a block diagram illustrating interactions between an exemplary LiDAR system and multiple other systems including a vehicle perception and planning system.

FIG. 3 is a block diagram illustrating an exemplary LiDAR system.

FIG. 4 is a block diagram illustrating an exemplary fiber-based laser source.

FIGS. 5A-5C illustrate an exemplary LiDAR system using pulse signals to measure distances to objects disposed in a field-of-view (FOV).

FIG. 6 is a block diagram illustrating an exemplary apparatus used to implement systems, apparatus, and methods in various embodiments.

FIG. 7 is a block diagram illustrating a fiber-based laser source including polyphase pump diodes and associated control circuitry according to one embodiment.

FIG. 8 is an exemplary control circuit according to one embodiment.

FIG. 9 is another exemplary control circuit according to one embodiment.

FIG. 10 is another exemplary control circuit according to one embodiment.

FIG. 11 illustrates an exemplary timing diagram representing a sequence of laser pump control signals.

FIG. 12 illustrates a comparison between a higher laser pump peak current and a lower laser pump peak current.

FIG. 13 illustrates a method in accordance with one embodiment.

FIG. 14 illustrates another method in accordance with on embodiment.

### DETAILED DESCRIPTION

To provide a more thorough understanding of the present invention, the following description sets forth numerous specific details, such as specific configurations, parameters, examples, and the like. It should be recognized, however, that such description is not intended as a limitation on the scope of the present invention but is intended to provide a better description of the exemplary embodiments.

Throughout the specification and claims, the following terms take the meanings explicitly associated herein, unless the context clearly dictates otherwise:

The phrase “in one embodiment” as used herein does not necessarily refer to the same embodiment, though it may. Thus, as described below, various embodiments of the disclosure may be readily combined, without departing from the scope or spirit of the invention.

As used herein, the term “or” is an inclusive “or” operator and is equivalent to the term “and/or,” unless the context clearly dictates otherwise.

The term “based on” is not exclusive and allows for being based on additional factors not described unless the context clearly dictates otherwise.

As used herein, and unless the context dictates otherwise, the term “coupled to” is intended to include both direct coupling (in which two elements that are coupled to each other contact each other) and indirect coupling (in which at least one additional element is located between the two elements). Therefore, the terms “coupled to” and “coupled with” are used synonymously. Within the context of a networked environment where two or more components or devices are able to exchange data, the terms “coupled to” and “coupled with” are also used to mean “communicatively coupled with”, possibly via one or more intermediary devices.

Although the following description uses the terms “first,” “second,” etc. to describe various elements, these elements should not be limited by the terms. These terms are only used to distinguish one element from another. For example, a first transistor could be termed a second transistor and, similarly, a second transistor could be termed a first transistor, without departing from the scope of the various described examples. The first transistor and the second transistor can both be transistors and, in some cases, can be separate and different transistors.

In addition, throughout the specification, the meaning of “a”, “an”, and “the” includes plural references, and the meaning of “in” includes “in” and “on”.

Although some of the various embodiments presented herein constitute a single combination of inventive elements, it should be appreciated that the inventive subject matter is considered to include all possible combinations of the disclosed elements. As such, if one embodiment comprises elements A, B, and C, and another embodiment comprises elements B and D, then the inventive subject matter is also considered to include other remaining combinations of A, B, C, or D, even if not explicitly discussed herein. Further, the transitional term “comprising” means to have as parts or members, or to be those parts or members. As used herein, the transitional term “comprising” is inclusive or open-ended and does not exclude additional, unrecited elements or method steps.

Throughout the following disclosure, numerous references may be made regarding servers, services, interfaces, engines, modules, clients, peers, portals, platforms, or other systems formed from computing devices. It should be appreciated that the use of such terms is deemed to represent one or more computing devices having at least one processor (e.g., ASIC, FPGA, PLD, DSP, x86, ARM, RISC-V, ColdFire, GPU, multi-core processors, etc.) configured to execute software instructions stored on a computer readable tangible, non-transitory medium (e.g., hard drive, solid state drive, RAM, flash, ROM, etc.). For example, a server can include one or more computers operating as a web server, database server, or other type of computer server in a manner to fulfill described roles, responsibilities, or functions. One should further appreciate the disclosed computer-based algorithms, processes, methods, or other types of instruction sets can be embodied as a computer program product comprising a non-transitory, tangible computer readable medium storing the instructions that cause a processor to execute the disclosed steps. The various servers, systems, databases, or interfaces can exchange data using standardized protocols or algorithms, possibly based on HTTP, HTTPS, AES, public-private key exchanges, web service APIs, known financial transaction protocols, or other electronic information exchanging methods. Data exchanges can be conducted over a packet-switched network, a circuit-switched network, the Internet, LAN, WAN, VPN, or other type of network.

As used in the description herein and throughout the claims that follow, when a system, engine, server, device, module, or other computing element is described as being configured to perform or execute functions on data in a memory, the meaning of “configured to”, “operative to”, or “programmed to” is defined as one or more processors or cores of the computing element being programmed by a set of software instructions stored in the memory of the computing element to execute the set of functions on target data or data objects stored in the memory.

It should be noted that any language directed to a computer should be read to include any suitable combination of computing devices or network platforms, including servers, interfaces, systems, databases, agents, peers, engines, controllers, modules, or other types of computing devices operating individually or collectively. One should appreciate the computing devices comprise a processor configured to execute software instructions stored on a tangible, non-transitory computer readable storage medium (e.g., hard drive, FPGA, PLA, solid state drive, RAM, flash, ROM, etc.). The software instructions configure or program the computing device to provide the roles, responsibilities, or other functionality as discussed below with respect to the disclosed apparatus. Further, the disclosed technologies can be embodied as a computer program product that includes a non-transitory computer readable medium storing the software instructions that causes a processor to execute the disclosed steps associated with implementations of computer-based algorithms, processes, methods, or other instructions. In some embodiments, the various servers, systems, databases, or interfaces exchange data using standardized protocols or algorithms, possibly based on HTTP, HTTPS, AES, public-private key exchanges, web service APIs, known financial transaction protocols, or other electronic information exchanging methods. Data exchanges among devices can be conducted over a packet-switched network, the Internet, LAN, WAN, VPN, or other type of packet switched network; a circuit switched network; cell switched network; or other type of network.

The embodiments of the present invention include some circuits idea and control methods to improve overall efficiency and reliability of pump laser section of a fiber laser.

A MOPA fiber laser is composed of seed laser, pump laser, pump/seed combiner and double cladding gain fiber as major components. In addition to these components, there are passive components to form a complete fiber laser. Among these components, reliability of pump laser diode is the biggest concern. Beyond better diode design and manufacturing process, using redundant laser diodes is another way to address this issue at the system level.

How to construct the driving circuit and how to operate these circuits also play important roles in improving system reliability.

Embodiments of the present invention are described below.

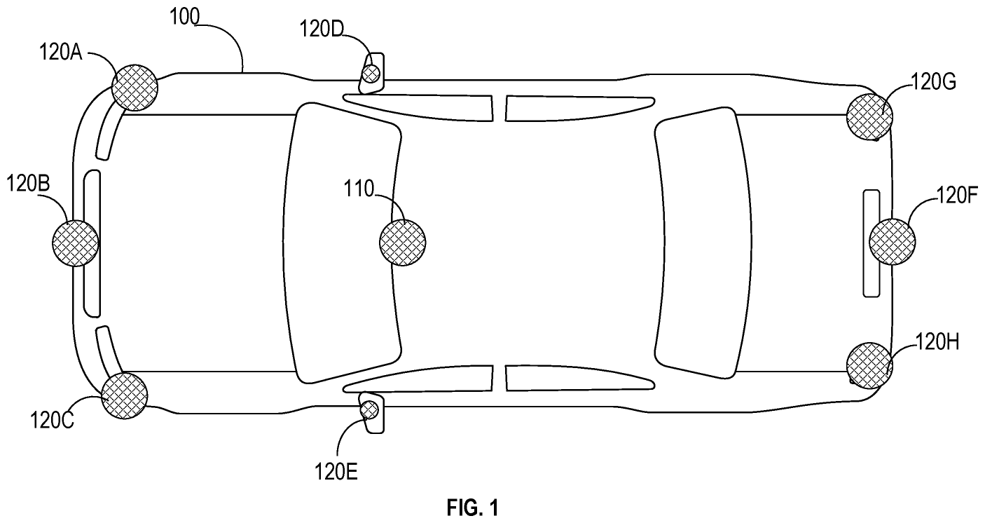

FIG. 1 illustrates one or more exemplary LiDAR systems 110 and 120A-120H disposed or included in a motor vehicle 100. Vehicle 100 can be a car, a sport utility vehicle (SUV), a truck, a train, a wagon, a bicycle, a motorcycle, a tricycle, a bus, a mobility scooter, a tram, a ship, a boat, an underwater vehicle, an airplane, a helicopter, an unmanned aviation vehicle (UAV), a spacecraft, etc. Motor vehicle 100 can be a vehicle having any automated level. For example, motor vehicle 100 can be a partially automated vehicle, a highly automated vehicle, a fully automated vehicle, or a driverless vehicle. A partially automated vehicle can perform some driving functions without a human driver's intervention. For example, a partially automated vehicle can perform blind-spot monitoring, lane keeping and/or lane changing operations, automated emergency braking, smart cruising and/or traffic following, or the like. Certain operations of a partially automated vehicle may be limited to specific applications or driving scenarios (e.g., limited to only freeway driving). A highly automated vehicle can generally perform all operations of a partially automated vehicle but with less limitations. A highly automated vehicle can also detect its own limits in operating the vehicle and ask the driver to take over the control of the vehicle when necessary. A fully automated vehicle can perform all vehicle operations without a driver's intervention but can also detect its own limits and ask the driver to take over when necessary. A driverless vehicle can operate on its own without any driver intervention.

In typical configurations, motor vehicle 100 comprises one or more LiDAR systems 110 and 120A-F. Each of LiDAR systems 110 and 120A-F can be a scanning-based LiDAR system and/or a non-scanning LiDAR system (e.g., a flash LiDAR). A scanning-based LiDAR system scans one or more light beams in one or more directions (e.g., horizontal and vertical directions) to detect objects in a field-of-view (FOV). A non-scanning based LiDAR system transmits laser light to illuminate an FOV without scanning. For example, a flash LiDAR is a type of non-scanning based LiDAR system. A flash LiDAR can transmit laser light to simultaneously illuminate an FOV using a single light pulse or light shot.

A LiDAR system is often an essential sensor of a vehicle that is at least partially automated. In one embodiment, as shown in FIG. 1, motor vehicle 100 may include a single LiDAR system 110 (e.g., without LiDAR systems 120A-F) disposed at the highest position of the vehicle (e.g., at the vehicle roof). Disposing LiDAR system 110 at the vehicle roof facilitates a 360-degree scanning around vehicle 100. In some other embodiments, motor vehicle 100 can include multiple LiDAR systems, including two or more of systems 110 and/or 120A-F. As shown in FIG. 1, in one embodiment, multiple LiDAR systems 110 and/or 120A-F are attached to vehicle 100 at different locations of the vehicle. For example, LiDAR system 120A is attached to vehicle 100 at the front right corner; LiDAR system 120B is attached to vehicle 100 at the front center; LiDAR system 120C is attached to vehicle 100 at the front left corner; LiDAR system 120D is attached to vehicle 100 at the right-side rear view mirror; LiDAR system 120E is attached to vehicle 100 at the left-side rear view mirror; and/or LiDAR system 120F is attached to vehicle 100 at the back center. In some embodiments, LiDAR systems 110 and 120A-F are independent LiDAR systems having their own respective laser sources, control electronics, transmitters, receivers, and/or steering mechanisms. In other embodiments, some of LiDAR systems 110 and 120A-F can share one or more components, thereby forming a distributed sensor system. In one example, optical fibers are used to deliver laser light from a centralized laser source to all LiDAR systems. It is understood that one or more LiDAR systems can be distributed and attached to a vehicle in any desired manner and FIG. 1 only illustrates one embodiment. As another example, LiDAR systems 120D and 120E may be attached to the B-pillars of vehicle 100 instead of the rear-view mirrors. As another example, LiDAR system 120B may be attached to the windshield of vehicle 100 instead of the front bumper.

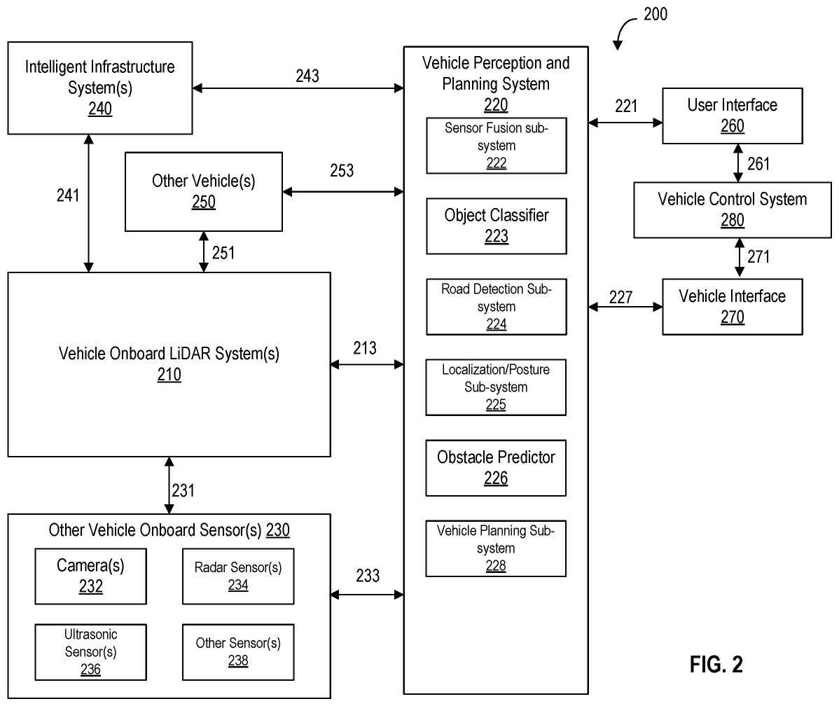

FIG. 2 is a block diagram 200 illustrating interactions between vehicle onboard LiDAR system(s) 210 and multiple other systems including a vehicle perception and planning system 220. LiDAR system(s) 210 can be mounted on or integrated to a vehicle. LiDAR system(s) 210 include sensor(s) that scan laser light to the surrounding environment to measure the distance, angle, and/or velocity of objects. Based on the scattered light that returned to LiDAR system(s) 210, it can generate sensor data (e.g., image data or 3D point cloud data) representing the perceived external environment.

LiDAR system(s) 210 can include one or more of short-range LiDAR sensors, medium-range LiDAR sensors, and long-range LiDAR sensors. A short-range LiDAR sensor measures objects located up to about 20-40 meters from the LiDAR sensor. Short-range LiDAR sensors can be used for, e.g., monitoring nearby moving objects (e.g., pedestrians crossing street in a school zone), parking assistance applications, or the like. A medium-range LiDAR sensor measures objects located up to about 100-150 meters from the LiDAR sensor. Medium-range LiDAR sensors can be used for, e.g., monitoring road intersections, assistance for merging onto or leaving a freeway, or the like. A long-range LiDAR sensor measures objects located up to about 150-300 meters. Long-range LiDAR sensors are typically used when a vehicle is travelling at high speed (e.g., on a freeway), such that the vehicle's control systems may only have a few seconds (e.g., 6-8 seconds) to respond to any situations detected by the LiDAR sensor. As shown in FIG. 2, in one embodiment, the LiDAR sensor data can be provided to vehicle perception and planning system 220 via a communication path 213 for further processing and controlling the vehicle operations. Communication path 213 can be any wired or wireless communication links that can transfer data.

With reference still to FIG. 2, in some embodiments, other vehicle onboard sensor(s) 230 are used to provide additional sensor data separately or together with LiDAR system(s) 210. Other vehicle onboard sensors 230 may include, for example, one or more camera(s) 232, one or more radar(s) 234, one or more ultrasonic sensor(s) 236, and/or other sensor(s) 238. Camera(s) 232 can take images and/or videos of the external environment of a vehicle. Camera(s) 232 can take, for example, high-definition (HD) videos having millions of pixels in each frame. A camera produces monochrome or color images and videos. Color information may be important in interpreting data for some situations (e.g., interpreting images of traffic lights). Color information may not be available from other sensors such as LiDAR or radar sensors. Camera(s) 232 can include one or more of narrow-focus cameras, wider-focus cameras, side-facing cameras, infrared cameras, fisheye cameras, or the like. The image and/or video data generated by camera(s) 232 can also be provided to vehicle perception and planning system 220 via communication path 233 for further processing and controlling the vehicle operations. Communication path 233 can be any wired or wireless communication links that can transfer data.

Other vehicle onboard sensos(s) 230 can also include radar sensor(s) 234. Radar sensor(s) 234 use radio waves to determine the range, angle, and velocity of objects. Radar sensor(s) 234 produce electromagnetic waves in the radio or microwave spectrum. The electromagnetic waves reflect off an object and some of the reflected waves return to the radar sensor, thereby providing information about the object's position and velocity. Radar sensor(s) 234 can include one or more of short-range radar(s), medium-range radar(s), and long-range radar(s). A short-range radar measures objects located at about 0.1-30 meters from the radar. A short-range radar is useful in detecting objects located nearby the vehicle, such as other vehicles, buildings, walls, pedestrians, bicyclists, etc. A short-range radar can be used to detect a blind spot, assist in lane changing, provide rear-end collision warning, assist in parking, provide emergency braking, or the like. A medium-range radar measures objects located at about 30-80 meters from the radar. A long-range radar measures objects located at about 80-200 meters. Medium- and/or long-range radars can be useful in, for example, traffic following, adaptive cruise control, and/or highway automatic braking. Sensor data generated by radar sensor(s) 234 can also be provided to vehicle perception and planning system 220 via communication path 233 for further processing and controlling the vehicle operations.

Other vehicle onboard sensor(s) 230 can also include ultrasonic sensor(s) 236. Ultrasonic sensor(s) 236 use acoustic waves or pulses to measure objects located external to a vehicle. The acoustic waves generated by ultrasonic sensor(s) 236 are transmitted to the surrounding environment. At least some of the transmitted waves are reflected off an object and return to the ultrasonic sensor(s) 236. Based on the return signals, a distance of the object can be calculated. Ultrasonic sensor(s) 236 can be useful in, for example, check blind spot, identify parking spots, provide lane changing assistance into traffic, or the like. Sensor data generated by ultrasonic sensor(s) 236 can also be provided to vehicle perception and planning system 220 via communication path 233 for further processing and controlling the vehicle operations.

In some embodiments, one or more other sensor(s) 238 may be attached in a vehicle and may also generate sensor data. Other sensor(s) 238 may include, for example, global positioning systems (GPS), inertial measurement units (IMU), or the like. Sensor data generated by other sensor(s) 238 can also be provided to vehicle perception and planning system 220 via communication path 233 for further processing and controlling the vehicle operations. It is understood that communication path 233 may include one or more communication links to transfer data between the various sensor(s) 230 and vehicle perception and planning system 220.

In some embodiments, as shown in FIG. 2, sensor data from other vehicle onboard sensor(s) 230 can be provided to vehicle onboard LiDAR system(s) 210 via communication path 231. LiDAR system(s) 210 may process the sensor data from other vehicle onboard sensor(s) 230. For example, sensor data from camera(s) 232, radar sensor(s) 234, ultrasonic sensor(s) 236, and/or other sensor(s) 238 may be correlated or fused with sensor data LiDAR system(s) 210, thereby at least partially offloading the sensor fusion process performed by vehicle perception and planning system 220. It is understood that other configurations may also be implemented for transmitting and processing sensor data from the various sensors (e.g., data can be transmitted to a cloud service for processing and then the processing results can be transmitted back to the vehicle perception and planning system 220).

With reference still to FIG. 2, in some embodiments, sensors onboard other vehicle(s) 250 are used to provide additional sensor data separately or together with LiDAR system(s) 210. For example, two or more nearby vehicles may have their own respective LiDAR sensor(s), camera(s), radar sensor(s), ultrasonic sensor(s), etc. Nearby vehicles can communicate and share sensor data with one another. Communications between vehicles are also referred to as V2V (vehicle to vehicle) communications. For example, as shown in FIG. 2, sensor data generated by other vehicle(s) 250 can be communicated to vehicle perception and planning system 220 and/or vehicle onboard LiDAR system(s) 210, via communication path 253 and/or communication path 251, respectively. Communication paths 253 and 251 can be any wired or wireless communication links that can transfer data.

Sharing sensor data facilitates a better perception of the environment external to the vehicles. For instance, a first vehicle may not sense a pedestrian that is a behind a second vehicle but is approaching the first vehicle. The second vehicle may share the sensor data related to this pedestrian with the first vehicle such that the first vehicle can have additional reaction time to avoid collision with the pedestrian. In some embodiments, similar to data generated by sensor(s) 230, data generated by sensors onboard other vehicle(s) 250 may be correlated or fused with sensor data generated by LiDAR system(s) 210, thereby at least partially offloading the sensor fusion process performed by vehicle perception and planning system 220.

In some embodiments, intelligent infrastructure system(s) 240 are used to provide sensor data separately or together with LiDAR system(s) 210. Certain infrastructures may be configured to communicate with a vehicle to convey information and vice versa. Communications between a vehicle and infrastructures are generally referred to as V2I (vehicle to infrastructure) communications. For example, intelligent infrastructure system(s) 240 may include an intelligent traffic light that can convey its status to an approaching vehicle in a message such as “changing to yellow in 5 seconds.” Intelligent infrastructure system(s) 240 may also include its own LiDAR system mounted near an intersection such that it can convey traffic monitoring information to a vehicle. For example, a left-turning vehicle at an intersection may not have sufficient sensing capabilities because some of its own sensors may be blocked by traffic in the opposite direction. In such a situation, sensors of intelligent infrastructure system(s) 240 can provide useful, and sometimes vital, data to the left-turning vehicle. Such data may include, for example, traffic conditions, information of objects in the direction the vehicle is turning to, traffic light status and predictions, or the like. These sensor data generated by intelligent infrastructure system(s) 240 can be provided to vehicle perception and planning system 220 and/or vehicle onboard LiDAR system(s) 210, via communication paths 243 and/or 241, respectively. Communication paths 243 and/or 241 can include any wired or wireless communication links that can transfer data. For example, sensor data from intelligent infrastructure system(s) 240 may be transmitted to LiDAR system(s) 210 and correlated or fused with sensor data generated by LiDAR system(s) 210, thereby at least partially offloading the sensor fusion process performed by vehicle perception and planning system 220. V2V and V2I communications described above are examples of vehicle-to-X (V2X) communications, where the “X” represents any other devices, systems, sensors, infrastructure, or the like that can share data with a vehicle.

With reference still to FIG. 2, via various communication paths, vehicle perception and planning system 220 receives sensor data from one or more of LiDAR system(s) 210, other vehicle onboard sensor(s) 230, other vehicle(s) 250, and/or intelligent infrastructure system(s) 240. In some embodiments, different types of sensor data are correlated and/or integrated by a sensor fusion sub-system 222. For example, sensor fusion sub-system 222 can generate a 360-degree model using multiple images or videos captured by multiple cameras disposed at different positions of the vehicle. Sensor fusion sub-system 222 obtains sensor data from different types of sensors and uses the combined data to perceive the environment more accurately. For example, a vehicle onboard camera 232 may not capture a clear image because it is facing the sun or a light source (e.g., another vehicle's headlight during nighttime) directly. A LiDAR system 210 may not be affected as much and therefore sensor fusion sub-system 222 can combine sensor data provided by both camera 232 and LiDAR system 210, and use the sensor data provided by LiDAR system 210 to compensate the unclear image captured by camera 232. As another example, in a rainy or foggy weather, a radar sensor 234 may work better than a camera 232 or a LiDAR system 210. Accordingly, sensor fusion sub-system 222 may use sensor data provided by the radar sensor 234 to compensate the sensor data provided by camera 232 or LiDAR system 210.

In other examples, sensor data generated by other vehicle onboard sensor(s) 230 may have a lower resolution (e.g., radar sensor data) and thus may need to be correlated and confirmed by LiDAR system(s) 210, which usually has a higher resolution. For example, a sewage cover (also referred to as a manhole cover) may be detected by radar sensor 234 as an object towards which a vehicle is approaching. Due to the low-resolution nature of radar sensor 234, vehicle perception and planning system 220 may not be able to determine whether the object is an obstacle that the vehicle needs to avoid. High-resolution sensor data generated by LiDAR system(s) 210 thus can be used to correlated and confirm that the object is a sewage cover and causes no harm to the vehicle.

Vehicle perception and planning system 220 further comprises an object classifier 223. Using raw sensor data and/or correlated/fused data provided by sensor fusion sub-system 222, object classifier 223 can detect and classify the objects and estimate the positions of the objects. In some embodiments, object classifier 233 can use machine-learning based techniques to detect and classify objects. Examples of the machine-learning based techniques include utilizing algorithms such as region-based convolutional neural networks (R-CNN), Fast R-CNN, Faster R-CNN, histogram of oriented gradients (HOG), region-based fully convolutional network (R-FCN), single shot detector (SSD), spatial pyramid pooling (SPP-net), and/or You Only Look Once (Yolo).

Vehicle perception and planning system 220 further comprises a road detection sub-system 224. Road detection sub-system 224 localizes the road and identifies objects and/or markings on the road. For example, based on raw or fused sensor data provided by radar sensor(s) 234, camera(s) 232, and/or LiDAR system(s) 210, road detection sub-system 224 can build a 3D model of the road based on machine-learning techniques (e.g., pattern recognition algorithms for identifying lanes). Using the 3D model of the road, road detection sub-system 224 can identify objects (e.g., obstacles or debris on the road) and/or markings on the road (e.g., lane lines, turning marks, crosswalk marks, or the like).

Vehicle perception and planning system 220 further comprises a localization and vehicle posture sub-system 225. Based on raw or fused sensor data, localization, and vehicle posture sub-system 225 can determine the position of the vehicle and the vehicle's posture. For example, using sensor data from LiDAR system(s) 210, camera(s) 232, and/or GPS data, localization, and vehicle posture sub-system 225 can determine an accurate position of the vehicle on the road and the vehicle's six degrees of freedom (e.g., whether the vehicle is moving forward or backward, up or down, and left or right). In some embodiments, high-definition (HD) maps are used for vehicle localization. HD maps can provide highly detailed, three-dimensional, computerized maps that pinpoint a vehicle's location. For instance, using the HD maps, localization, and vehicle posture sub-system 225 can precisely determine the vehicle's current position (e.g., which lane of the road the vehicle is currently in, how close it is to a curb or a sidewalk) and predict vehicle's future positions.

Vehicle perception and planning system 220 further comprises obstacle predictor 226. Objects identified by object classifier 223 can be stationary (e.g., a light pole, a road sign) or dynamic (e.g., a moving pedestrian, bicycle, another car). For moving objects, predicting their moving path or future positions can be important to avoid collision. Obstacle predictor 226 can predict an obstacle trajectory and/or warn the driver or the vehicle planning sub-system 228 about a potential collision. For example, if there is a high likelihood that the obstacle's trajectory intersects with the vehicle's current moving path, obstacle predictor 226 can generate such a warning. Obstacle predictor 226 can use a variety of techniques for making such a prediction. Such techniques include, for example, constant velocity or acceleration models, constant turn rate and velocity/acceleration models, Kalman Filter and Extended Kalman Filter based models, recurrent neural network (RNN) based models, long short-term memory (LSTM) neural network based models, encoder-decoder RNN models, or the like.

With reference still to FIG. 2, in some embodiments, vehicle perception and planning system 220 further comprises vehicle planning sub-system 228. Vehicle planning sub-system 228 can include a route planner, a driving behaviors planner, and a motion planner. The route planner can plan the route of a vehicle based on the vehicle's current location data, target location data, traffic information, etc. The driving behavior planner adjusts the timing and planned movement based on how other objects might move, using the obstacle prediction results provided by obstacle predictor 226. The motion planner determines the specific operations the vehicle needs to follow. The planning results are then communicated to vehicle control system 280 via vehicle interface 270. The communication can be performed through communication paths 227 and 271, which include any wired or wireless communication links that can transfer data.

Vehicle control system 280 controls the vehicle's steering mechanism, throttle, brake, etc., to operate the vehicle according to the planned route and movement. Vehicle perception and planning system 220 may further comprise a user interface 260, which provides a user (e.g., a driver) access to vehicle control system 280 to, for example, override or take over control of the vehicle when necessary. User interface 260 can communicate with vehicle perception and planning system 220, for example, to obtain and display raw or fused sensor data, identified objects, vehicle's location/posture, etc. These displayed data can help a user to better operate the vehicle. User interface 260 can communicate with vehicle perception and planning system 220 and/or vehicle control system 280 via communication paths 221 and 261 respectively, which include any wired or wireless communication links that can transfer data. It is understood that the various systems, sensors, communication links, and interfaces in FIG. 2 can be configured in any desired manner and not limited to the configuration shown in FIG. 2.

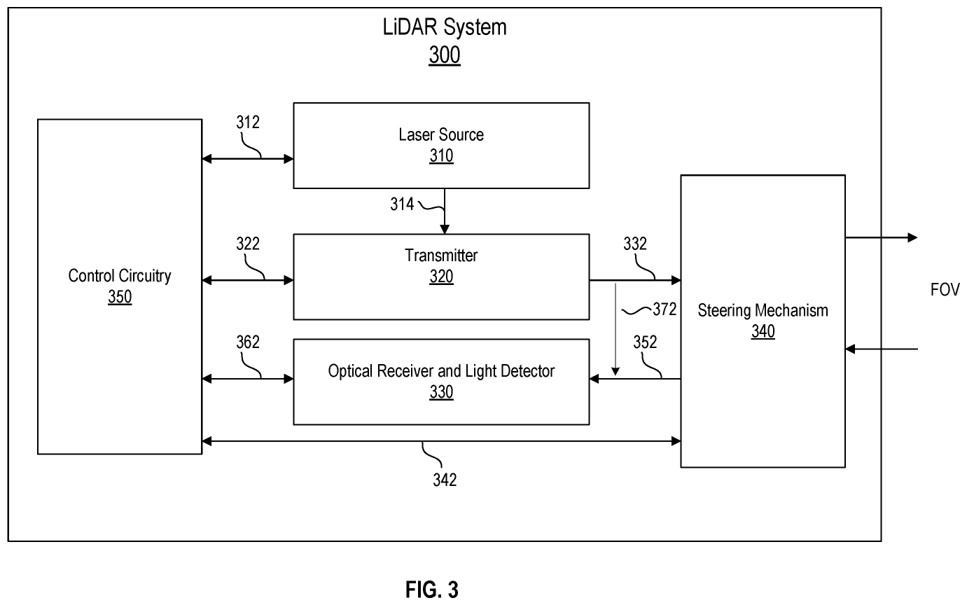

FIG. 3 is a block diagram illustrating an exemplary LiDAR system 300. LiDAR system 300 can be used to implement LiDAR system 110, 120A-H, and/or 210 shown in FIGS. 1 and 2. In one embodiment, LiDAR system 300 comprises a laser source 310, a transmitter 320, an optical receiver and light detector 330, a steering system 340, and a control circuitry 350. These components are coupled together using communications paths 312, 314, 322, 332, 343, 352, and 362. These communications paths include communication links (wired or wireless, bidirectional or unidirectional) among the various LiDAR system components, but need not be physical components themselves. While the communications paths can be implemented by one or more electrical wires, buses, or optical fibers, the communication paths can also be wireless channels or free-space optical paths so that no physical communication medium is present. For example, in one embodiment of LiDAR system 300, communication path 314 between laser source 310 and transmitter 320 may be implemented using one or more optical fibers. Communication paths 332 and 352 may represent optical paths implemented using free space optical components and/or optical fibers. And communication paths 312, 322, 342, and 362 may be implemented using one or more electrical wires that carry electrical signals. The communications paths can also include one or more of the above types of communication mediums (e.g., they can include an optical fiber and a free-space optical component, or include one or more optical fibers and one or more electrical wires).

In some embodiments, LiDAR system 300 can be a coherent LiDAR system. One example is a frequency-modulated continuous-wave (FMCW) LiDAR. Coherent LiDARs detects objects by mixing return light from the objects with light from the coherent laser transmitter. Thus, as shown in FIG. 3, if LiDAR system 300 is a coherent LiDAR, it may include a route 372 providing a portion of transmission light from transmitter 320 to optical receiver and light detector 330. Route 372 may include one or more optics (e.g., optical fibers, lens, mirrors, etc.) for providing the light from transmitter 320 to optical receiver and light detector 330. The transmission light provided by transmitter 320 may be modulated light and can be split into two portions. One portion is transmitted to the FOV, while the second portion is sent to the optical receiver and light detector of the LiDAR system. The second portion is also referred to as the light that is kept local (LO) to the LiDAR system. The transmission light is scattered or reflected by various objects in the FOV and at least a portion of it forms return light. The return light is subsequently detected and interferometrically recombined with the second portion of the transmission light that was kept local. Coherent LiDAR provides a means of optically sensing an object's range as well as its relative velocity along the line-of-sight (LOS).

LiDAR system 300 can also include other components not depicted in FIG. 3, such as power buses, power supplies, LED indicators, switches, etc. Additionally, other communication connections among components may be present, such as a direct connection between light source 310 and optical receiver and light detector 330 to provide a reference signal so that the time from when a light pulse is transmitted until a return light pulse is detected can be accurately measured.

Laser source 310 outputs laser light for illuminating objects in a field of view (FOV). Laser source 310 can be, for example, a semiconductor-based laser (e.g., a diode laser) and/or a fiber-based laser. A semiconductor-based laser can be, for example, an edge emitting laser (EEL), a vertical cavity surface emitting laser (VCSEL), or the like. A fiber-based laser is a laser in which the active gain medium is an optical fiber doped with rare-earth elements such as erbium, ytterbium, neodymium, dysprosium, praseodymium, thulium and/or holmium. In some embodiments, a fiber laser is based on double-clad fibers, in which the gain medium forms the core of the fiber surrounded by two layers of cladding. The double-clad fiber allows the core to be pumped with a high-power beam, thereby enabling the laser source to be a high power fiber laser source.

In some embodiments, laser source 310 comprises a master oscillator (also referred to as a seed laser) and power amplifier (MOPA). The power amplifier amplifies the output power of the seed laser. The power amplifier can be a fiber amplifier, a bulk amplifier, or a semiconductor optical amplifier. The seed laser can be a diode laser (e.g., a Fabry-Perot cavity laser, a distributed feedback laser), a solid-state bulk laser, or a tunable external-cavity diode laser. In some embodiments, laser source 310 can be an optically pumped microchip laser. Microchip lasers are alignment-free monolithic solid-state lasers where the laser crystal is directly contacted with the end mirrors of the laser resonator. A microchip laser is typically pumped with a laser diode (directly or using a fiber) to obtain the desired output power. A microchip laser can be based on neodymium-doped yttrium aluminum garnet (Y₃Al₅O₁₂) laser crystals (i.e., Nd:YAG), or neodymium-doped vanadate (i.e., ND:YVO₄) laser crystals.

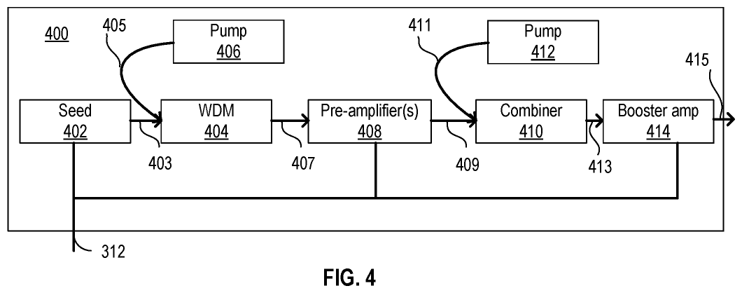

FIG. 4 is a block diagram illustrating an exemplary fiber-based laser source 400 having a seed laser and one or more pumps (e.g., laser diodes) for pumping desired output power. Fiber-based laser source 400 is an example of laser source 310 depicted in FIG. 3. In some embodiments, fiber-based laser source 400 comprises a seed laser 402 to generate initial light pulses of one or more wavelengths (e.g., 1550 nm), which are provided to a wavelength-division multiplexor (WDM) 404 via an optical fiber 403. Fiber-based laser source 400 further comprises a pump 406 for providing laser power (e.g., of a different wavelength, such as 980 nm) to WDM 404 via an optical fiber 405. WDM 404 multiplexes the light pulses provided by seed laser 402 and the laser power provided by pump 406 onto a single optical fiber 407. The output of WDM 404 can then be provided to one or more pre-amplifier(s) 408 via optical fiber 407. Pre-amplifier(s) 408 can be optical amplifier(s) that amplify optical signals (e.g., with about 20-30 dB gain). In some embodiments, pre-amplifier(s) 408 are low noise amplifiers. Pre-amplifier(s) 408 output to a combiner 410 via an optical fiber 409. Combiner 410 combines the output laser light of pre-amplifier(s) 408 with the laser power provided by pump 412 via an optical fiber 411. Combiner 410 can combine optical signals having the same wavelength or different wavelengths. One example of a combiner is a WDM. Combiner 410 provides pulses to a booster amplifier 414, which produces output light pulses via optical fiber 415. The booster amplifier 414 provides further amplification of the optical signals. The output light pulses can then be transmitted to transmitter 320 and/or steering mechanism 340 (shown in FIG. 3). It is understood that FIG. 4 illustrates one exemplary configuration of fiber-based laser source 400. Laser source 400 can have many other configurations using different combinations of one or more components shown in FIG. 4 and/or other components not shown in FIG. 4 (e.g., other components such as power supplies, lens, filters, splitters, combiners, etc.).

In some variations, fiber-based laser source 400 can be controlled (e.g., by control circuitry 350) to produce pulses of different amplitudes based on the fiber gain profile of the fiber used in fiber-based laser source 400. Communication path 312 couples fiber-based laser source 400 to control circuitry 350 (shown in FIG. 3) so that components of fiber-based laser source 400 can be controlled by or otherwise communicate with control circuitry 350. Alternatively, fiber-based laser source 400 may include its own dedicated controller. Instead of control circuitry 350 communicating directly with components of fiber-based laser source 400, a dedicated controller of fiber-based laser source 400 communicates with control circuitry 350 and controls and/or communicates with the components of fiber-based light source 400. Fiber-based light source 400 can also include other components not shown, such as one or more power connectors, power supplies, and/or power lines.

Referencing FIG. 3, typical operating wavelengths of laser source 310 comprise, for example, about 850 nm, about 905 nm, about 940 nm, about 1064 nm, and about 1550 nm. The upper limit of maximum usable laser power is set by the U.S. FDA (U.S. Food and Drug Administration) regulations. The optical power limit at 1550 nm wavelength is much higher than those of the other aforementioned wavelengths. Further, at 1550 nm, the optical power loss in a fiber is low. There characteristics of the 1550 nm wavelength make it more beneficial for long-range LiDAR applications. The amount of optical power output from laser source 310 can be characterized by its peak power, average power, and the pulse energy. The peak power is the ratio of pulse energy to the width of the pulse (e.g., full width at half maximum or FWHM). Thus, a smaller pulse width can provide a larger peak power for a fixed amount of pulse energy. A pulse width can be in the range of nanosecond or picosecond. The average power is the product of the energy of the pulse and the pulse repetition rate (PRR). As described in more detail below, the PRR represents the frequency of the pulsed laser light. The PRR typically corresponds to the maximum range that a LiDAR system can measure. Laser source 310 can be configured to produce pulses at high PRR to meet the desired number of data points in a point cloud generated by the LiDAR system. Laser source 310 can also be configured to produce pulses at medium or low PRR to meet the desired maximum detection distance. Wall plug efficiency (WPE) is another factor to evaluate the total power consumption, which may be a key indicator in evaluating the laser efficiency. For example, as shown in FIG. 1, multiple LiDAR systems may be attached to a vehicle, which may be an electrical-powered vehicle or a vehicle otherwise having limited fuel or battery power supply. Therefore, high WPE and intelligent ways to use laser power are often among the important considerations when selecting and configuring laser source 310 and/or designing laser delivery systems for vehicle-mounted LiDAR applications.

It is understood that the above descriptions provide non-limiting examples of a laser source 310. Laser source 310 can be configured to include many other types of light sources (e.g., laser diodes, short-cavity fiber lasers, solid-state lasers, and/or tunable external cavity diode lasers) that are configured to generate one or more light signals at various wavelengths. In some examples, light source 310 comprises amplifiers (e.g., pre-amplifiers and/or booster amplifiers), which can be a doped optical fiber amplifier, a solid-state bulk amplifier, and/or a semiconductor optical amplifier. The amplifiers are configured to receive and amplify light signals with desired gains.

With reference back to FIG. 3, LiDAR system 300 further comprises a transmitter 320. Laser source 310 provides laser light (e.g., in the form of a laser beam) to transmitter 320. The laser light provided by laser source 310 can be amplified laser light with a predetermined or controlled wavelength, pulse repetition rate, and/or power level. Transmitter 320 receives the laser light from laser source 310 and transmits the laser light to steering mechanism 340 with low divergence. In some embodiments, transmitter 320 can include, for example, optical components (e.g., lens, fibers, mirrors, etc.) for transmitting laser beams to a field-of-view (FOV) directly or via steering mechanism 340. While FIG. 3 illustrates transmitter 320 and steering mechanism 340 as separate components, they may be combined or integrated as one system in some embodiments. Steering mechanism 340 is described in more detail below.

Laser beams provided by laser source 310 may diverge as they travel to transmitter 320. Therefore, transmitter 320 often comprises a collimating lens configured to collect the diverging laser beams and produce more parallel optical beams with reduced or minimum divergence. The collimated optical beams can then be further directed through various optics such as mirrors and lens. A collimating lens may be, for example, a single plano-convex lens or a lens group. The collimating lens can be configured to achieve any desired properties such as the beam diameter, divergence, numerical aperture, focal length, or the like. A beam propagation ratio or beam quality factor (also referred to as the M² factor) is used for measurement of laser beam quality. In many LiDAR applications, it is important to have good laser beam quality in the generated transmitting laser beam. The M² factor represents a degree of variation of a beam from an ideal Gaussian beam. Thus, the M² factor reflects how well a collimated laser beam can be focused on a small spot, or how well a divergent laser beam can be collimated. Therefore, laser source 310 and/or transmitter 320 can be configured to meet, for example, a scan resolution requirement while maintaining the desired M² factor.

One or more of the light beams provided by transmitter 320 are scanned by steering mechanism 340 to a FOV. Steering mechanism 340 scans light beams in multiple dimensions (e.g., in both the horizontal and vertical dimension) to facilitate LiDAR system 300 to map the environment by generating a 3D point cloud. Steering mechanism 340 will be described in more detail below. The laser light scanned to an FOV may be scattered or reflected by an object in the FOV. At least a portion of the scattered or reflected light returns to LiDAR system 300. FIG. 3 further illustrates an optical receiver and light detector 330 configured to receive the return light. Optical receiver and light detector 330 comprises an optical receiver that is configured to collect the return light from the FOV. The optical receiver can include optics (e.g., lens, fibers, mirrors, etc.) for receiving, redirecting, focus, amplifying, and/or filtering return light from the FOV. For example, the optical receiver often includes a collection lens (e.g., a single plano-convex lens or a lens group) to collect and/or focus the collected return light onto a light detector.

A light detector detects the return light focused by the optical receiver and generates current and/or voltage signals proportional to the incident intensity of the return light. Based on such current and/or voltage signals, the depth information of the object in the FOV can be derived. One exemplary method for deriving such depth information is based on the direct TOF (time of flight), which is described in more detail below. A light detector may be characterized by its detection sensitivity, quantum efficiency, detector bandwidth, linearity, signal to noise ratio (SNR), overload resistance, interference immunity, etc. Based on the applications, the light detector can be configured or customized to have any desired characteristics. For example, optical receiver and light detector 330 can be configured such that the light detector has a large dynamic range while having a good linearity. The light detector linearity indicates the detector's capability of maintaining linear relationship between input optical signal power and the detector's output. A detector having good linearity can maintain a linear relationship over a large dynamic input optical signal range.

To achieve desired detector characteristics, configurations or customizations can be made to the light detector's structure and/or the detector's material system. Various detector structure can be used for a light detector. For example, a light detector structure can be a PIN based structure, which has an undoped intrinsic semiconductor region (i.e., an “i” region) between a p-type semiconductor and an n-type semiconductor region. Other light detector structures comprise, for example, a APD (avalanche photodiode) based structure, a PMT (photomultiplier tube) based structure, a SiPM (Silicon photomultiplier) based structure, a SPAD (single-photon avalanche diode) base structure, and/or quantum wires. For material systems used in a light detector, Si, InGaAs, and/or Si/Ge based materials can be used. It is understood that many other detector structures and/or material systems can be used in optical receiver and light detector 330.

A light detector (e.g., an APD based detector) may have an internal gain such that the input signal is amplified when generating an output signal. However, noise may also be amplified due to the light detector's internal gain. Common types of noise include signal shot noise, dark current shot noise, thermal noise, and amplifier noise (TIA). In some embodiments, optical receiver and light detector 330 may include a pre-amplifier that is a low noise amplifier (LNA). In some embodiments, the pre-amplifier may also include a TIA-transimpedance amplifier, which converts a current signal to a voltage signal. For a linear detector system, input equivalent noise or noise equivalent power (NEP) measures how sensitive the light detector is to weak signals. Therefore, they can be used as indicators of the overall system performance. For example, the NEP of a light detector specifies the power of the weakest signal that can be detected and therefore it in turn specifies the maximum range of a LiDAR system. It is understood that various light detector optimization techniques can be used to meet the requirement of LiDAR system 300. Such optimization techniques may include selecting different detector structures, materials, and/or implement signal processing techniques (e.g., filtering, noise reduction, amplification, or the like). For example, in addition to or instead of using direct detection of return signals (e.g., by using TOF), coherent detection can also be used for a light detector. Coherent detection allows for detecting amplitude and phase information of the received light by interfering the received light with a local oscillator. Coherent detection can improve detection sensitivity and noise immunity.

FIG. 3 further illustrates that LiDAR system 300 comprises steering mechanism 340. As described above, steering mechanism 340 directs light beams from transmitter 320 to scan an FOV in multiple dimensions. A steering mechanism is referred to as a raster mechanism or a scanning mechanism. Scanning light beams in multiple directions (e.g., in both the horizontal and vertical directions) facilitates a LiDAR system to map the environment by generating an image or a 3D point cloud. A steering mechanism can be based on mechanical scanning and/or solid-state scanning. Mechanical scanning uses rotating mirrors to steer the laser beam or physically rotate the LiDAR transmitter and receiver (collectively referred to as transceiver) to scan the laser beam. Solid-state scanning directs the laser beam to various positions through the FOV without mechanically moving any macroscopic components such as the transceiver. Solid-state scanning mechanisms include, for example, optical phased arrays based steering and flash LiDAR based steering. In some embodiments, because solid-state scanning mechanisms do not physically move macroscopic components, the steering performed by a solid-state scanning mechanism may be referred to as effective steering. A LiDAR system using solid-state scanning may also be referred to as a non-mechanical scanning or simply non-scanning LiDAR system (a flash LiDAR system is an exemplary non-scanning LiDAR system).

Steering mechanism 340 can be used with the transceiver (e.g., transmitter 320 and optical receiver and light detector 330) to scan the FOV for generating an image or a 3D point cloud. As an example, to implement steering mechanism 340, a two-dimensional mechanical scanner can be used with a single-point or several single-point transceivers. A single-point transceiver transmits a single light beam or a small number of light beams (e.g., 2-8 beams) to the steering mechanism. A two-dimensional mechanical steering mechanism comprises, for example, polygon mirror(s), oscillating mirror(s), rotating prism(s), rotating tilt mirror surface(s), or a combination thereof. In some embodiments, steering mechanism 340 may include non-mechanical steering mechanism(s) such as solid-state steering mechanism(s). For example, steering mechanism 340 can be based on tuning wavelength of the laser light combined with refraction effect, and/or based on reconfigurable grating/phase array. In some embodiments, steering mechanism 340 can use a single scanning device to achieve two-dimensional scanning or two devices combined to realize two-dimensional scanning.

As another example, to implement steering mechanism 340, a one-dimensional mechanical scanner can be used with an array or a large number of single-point transceivers. Specifically, the transceiver array can be mounted on a rotating platform to achieve 360-degree horizontal field of view. Alternatively, a static transceiver array can be combined with the one-dimensional mechanical scanner. A one-dimensional mechanical scanner comprises polygon mirror(s), oscillating mirror(s), rotating prism(s), rotating tilt mirror surface(s) for obtaining a forward-looking horizontal field of view. Steering mechanisms using mechanical scanners can provide robustness and reliability in high volume production for automotive applications.

As another example, to implement steering mechanism 340, a two-dimensional transceiver can be used to generate a scan image or a 3D point cloud directly. In some embodiments, a stitching or micro shift method can be used to improve the resolution of the scan image or the field of view being scanned. For example, using a two-dimensional transceiver, signals generated at one direction (e.g., the horizontal direction) and signals generated at the other direction (e.g., the vertical direction) may be integrated, interleaved, and/or matched to generate a higher or full resolution image or 3D point cloud representing the scanned FOV.

Some implementations of steering mechanism 340 comprise one or more optical redirection elements (e.g., mirrors or lens) that steer return light signals (e.g., by rotating, vibrating, or directing) along a receive path to direct the return light signals to optical receiver and light detector 330. The optical redirection elements that direct light signals along the transmitting and receiving paths may be the same components (e.g., shared), separate components (e.g., dedicated), and/or a combination of shared and separate components. This means that in some cases the transmitting and receiving paths are different although they may partially overlap (or in some cases, substantially overlap).

With reference still to FIG. 3, LiDAR system 300 further comprises control circuitry 350. Control circuitry 350 can be configured and/or programmed to control various parts of the LiDAR system 300 and/or to perform signal processing. In a typical system, control circuitry 350 can be configured and/or programmed to perform one or more control operations including, for example, controlling laser source 310 to obtain desired laser pulse timing, repetition rate, and power; controlling steering mechanism 340 (e.g., controlling the speed, direction, and/or other parameters) to scan the FOV and maintain pixel registration/alignment; controlling optical receiver and light detector 330 (e.g., controlling the sensitivity, noise reduction, filtering, and/or other parameters) such that it is an optimal state; and monitoring overall system health/status for functional safety.

Control circuitry 350 can also be configured and/or programmed to perform signal processing to the raw data generated by optical receiver and light detector 330 to derive distance and reflectance information, and perform data packaging and communication to vehicle perception and planning system 220 (shown in FIG. 2). For example, control circuitry 350 determines the time it takes from transmitting a light pulse until a corresponding return light pulse is received; determines when a return light pulse is not received for a transmitted light pulse; determines the direction (e.g., horizontal and/or vertical information) for a transmitted/return light pulse; determines the estimated range in a particular direction; and/or determines any other type of data relevant to LiDAR system 300.

LiDAR system 300 can be disposed in a vehicle, which may operate in many different environments including hot or cold weather, rough road conditions that may cause intense vibration, high or low humidity, dusty areas, etc. Therefore, in some embodiments, optical and/or electronic components of LiDAR system 300 (e.g., optics in transmitter 320, optical receiver and light detector 330, and steering mechanism 340) are disposed or configured in such a manner to maintain long term mechanical and optical stability. For example, components in LiDAR system 300 may be secured and sealed such that they can operate under all conditions a vehicle may encounter. As an example, an anti-moisture coating and/or hermetic sealing may be applied to optical components of transmitter 320, optical receiver and light detector 330, and steering mechanism 340 (and other components that are susceptible to moisture). As another example, housing(s), enclosure(s), and/or window can be used in LiDAR system 300 for providing desired characteristics such as hardness, ingress protection (IP) rating, self-cleaning capability, resistance to chemical and resistance to impact, or the like. In addition, efficient and economical methodologies for assembling LiDAR system 300 may be used to meet the LiDAR operating requirements while keeping the cost low.

It is understood by a person of ordinary skill in the art that FIG. 3 and the above descriptions are for illustrative purposes only, and a LiDAR system can include other functional units, blocks, or segments, and can include variations or combinations of these above functional units, blocks, or segments. For example, LiDAR system 300 can also include other components not depicted in FIG. 3, such as power buses, power supplies, LED indicators, switches, etc. Additionally, other connections among components may be present, such as a direct connection between light source 310 and optical receiver and light detector 330 so that light detector 330 can accurately measure the time from when light source 310 transmits a light pulse until light detector 330 detects a return light pulse.

These components shown in FIG. 3 are coupled together using communications paths 312, 314, 322, 332, 342, 352, and 362. These communications paths represent communication (bidirectional or unidirectional) among the various LiDAR system components but need not be physical components themselves. While the communications paths can be implemented by one or more electrical wires, busses, or optical fibers, the communication paths can also be wireless channels or open-air optical paths so that no physical communication medium is present. For example, in one exemplary LiDAR system, communication path 314 includes one or more optical fibers; communication path 352 represents an optical path; and communication paths 312, 322, 342, and 362 are all electrical wires that carry electrical signals. The communication paths can also include more than one of the above types of communication mediums (e.g., they can include an optical fiber and an optical path, or one or more optical fibers and one or more electrical wires).

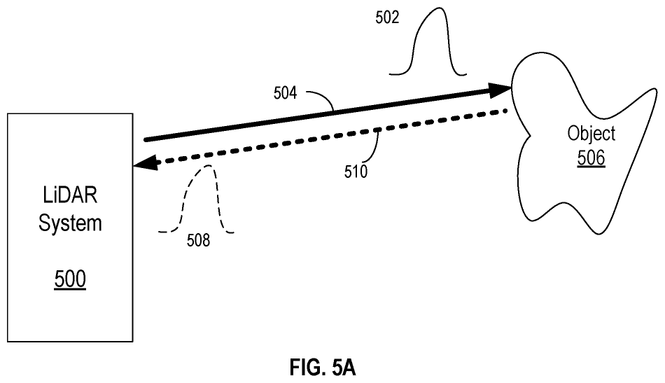

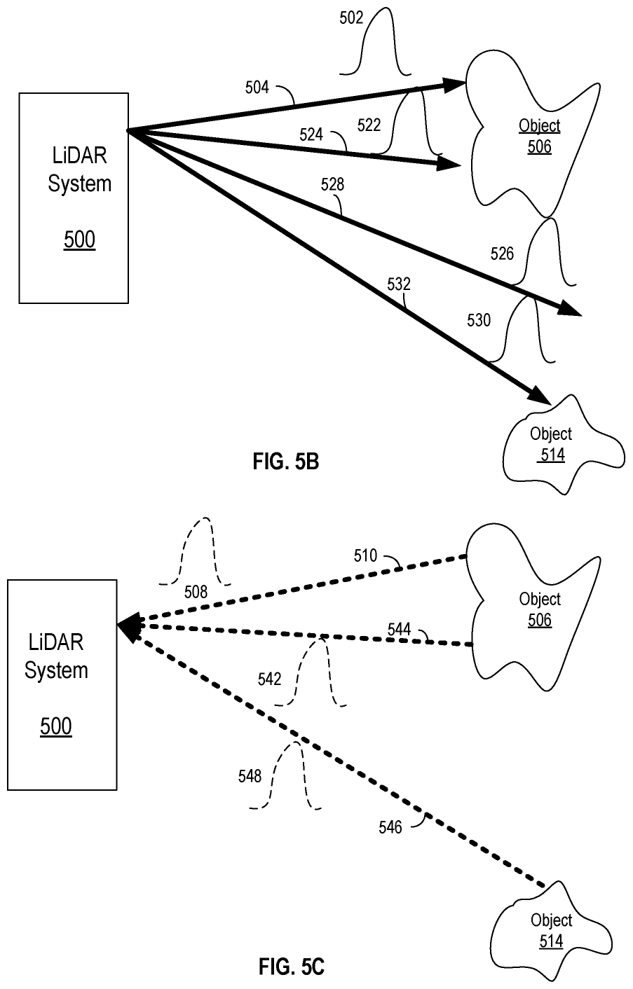

As described above, some LiDAR systems use the time-of-flight (TOF) of light signals (e.g., light pulses) to determine the distance to objects in a light path. For example, with reference to FIG. 5A, an exemplary LiDAR system 500 includes a laser light source (e.g., a fiber laser), a steering system (e.g., a system of one or more moving mirrors), and a light detector (e.g., a photon detector with one or more optics). LiDAR system 500 can be implemented using, for example, LiDAR system 300 described above. LiDAR system 500 transmits a light pulse 502 along light path 504 as determined by the steering system of LiDAR system 500. In the depicted example, light pulse 502, which is generated by the laser light source, is a short pulse of laser light. Further, the signal steering system of the LiDAR system 500 is a pulsed-signal steering system. However, it should be appreciated that LiDAR systems can operate by generating, transmitting, and detecting light signals that are not pulsed and derive ranges to an object in the surrounding environment using techniques other than time-of-flight. For example, some LiDAR systems use frequency modulated continuous waves (i.e., “FMCW”). It should be further appreciated that any of the techniques described herein with respect to time-of-flight based systems that use pulsed signals also may be applicable to LiDAR systems that do not use one or both of these techniques.

Referring back to FIG. 5A (e.g., illustrating a time-of-flight LiDAR system that uses light pulses), when light pulse 502 reaches object 506, light pulse 502 scatters or reflects to generate a return light pulse 508. Return light pulse 508 may return to system 500 along light path 510. The time from when transmitted light pulse 502 leaves LiDAR system 500 to when return light pulse 508 arrives back at LiDAR system 500 can be measured (e.g., by a processor or other electronics, such as control circuitry 350, within the LiDAR system). This time-of-flight combined with the knowledge of the speed of light can be used to determine the range/distance from LiDAR system 500 to the portion of object 506 where light pulse 502 scattered or reflected.

By directing many light pulses, as depicted in FIG. 5B, LiDAR system 500 scans the external environment (e.g., by directing light pulses 502, 522, 526, 530 along light paths 504, 524, 528, 532, respectively). As depicted in FIG. 5C, LiDAR system 500 receives return light pulses 508, 542, 548 (which correspond to transmitted light pulses 502, 522, 530, respectively). Return light pulses 508, 542, and 548 are generated by scattering or reflecting the transmitted light pulses by one of objects 506 and 514. Return light pulses 508, 542, and 548 may return to LiDAR system 500 along light paths 510, 544, and 546, respectively. Based on the direction of the transmitted light pulses (as determined by LiDAR system 500) as well as the calculated range from LiDAR system 500 to the portion of objects that scatter or reflect the light pulses (e.g., the portions of objects 506 and 514), the external environment within the detectable range (e.g., the field of view between path 504 and 532, inclusively) can be precisely mapped or plotted (e.g., by generating a 3D point cloud or images).

If a corresponding light pulse is not received for a particular transmitted light pulse, then it may be determined that there are no objects within a detectable range of LiDAR system 500 (e.g., an object is beyond the maximum scanning distance of LiDAR system 500). For example, in FIG. 5B, light pulse 526 may not have a corresponding return light pulse (as illustrated in FIG. 5C) because light pulse 526 may not produce a scattering event along its transmission path 528 within the predetermined detection range. LiDAR system 500, or an external system in communication with LiDAR system 500 (e.g., a cloud system or service), can interpret the lack of return light pulse as no object being disposed along light path 528 within the detectable range of LiDAR system 500.

In FIG. 5B, light pulses 502, 522, 526, and 530 can be transmitted in any order, serially, in parallel, or based on other timings with respect to each other. Additionally, while FIG. 5B depicts transmitted light pulses as being directed in one dimension or one plane (e.g., the plane of the paper), LiDAR system 500 can also direct transmitted light pulses along other dimension(s) or plane(s). For example, LiDAR system 500 can also direct transmitted light pulses in a dimension or plane that is perpendicular to the dimension or plane shown in FIG. 5B, thereby forming a 2-dimensional transmission of the light pulses. This 2-dimensional transmission of the light pulses can be point-by-point, line-by-line, all at once, or in some other manner. A point cloud or image from a 1-dimensional transmission of light pulses (e.g., a single horizontal line) can generate 2-dimensional data (e.g., (1) data from the horizontal transmission direction and (2) the range or distance to objects). Similarly, a point cloud or image from a 2-dimensional transmission of light pulses can generate 3-dimensional data (e.g., (1) data from the horizontal transmission direction, (2) data from the vertical transmission direction, and (3) the range or distance to objects). In general, a LiDAR system performing an n-dimensional transmission of light pulses generates (n+1) dimensional data. This is because the LiDAR system can measure the depth of an object or the range/distance to the object, which provides the extra dimension of data. Therefore, a 2D scanning by a LiDAR system can generate a 3D point cloud for mapping the external environment of the LiDAR system.

The density of a point cloud refers to the number of measurements (data points) per area performed by the LiDAR system. A point cloud density relates to the LiDAR scanning resolution. Typically, a larger point cloud density, and therefore a higher resolution, is desired at least for the region of interest (ROI). The density of points in a point cloud or image generated by a LiDAR system is equal to the number of pulses divided by the field of view. In some embodiments, the field of view can be fixed. Therefore, to increase the density of points generated by one set of transmission-receiving optics (or transceiver optics), the LiDAR system may need to generate a pulse more frequently. In other words, a light source with a higher pulse repetition rate (PRR) is needed. On the other hand, by generating and transmitting pulses more frequently, the farthest distance that the LiDAR system can detect may be limited. For example, if a return signal from a distant object is received after the system transmits the next pulse, the return signals may be detected in a different order than the order in which the corresponding signals are transmitted, thereby causing ambiguity if the system cannot correctly correlate the return signals with the transmitted signals.

To illustrate, consider an exemplary LiDAR system that can transmit laser pulses with a repetition rate between 500 kHz and 1 MHz. Based on the time it takes for a pulse to return to the LiDAR system and to avoid mix-up of return pulses from consecutive pulses in a conventional LiDAR design, the farthest distance the LiDAR system can detect may be 300 meters and 150 meters for 500 kHz and 1 MHz, respectively. The density of points of a LiDAR system with 500 kHz repetition rate is half of that with 1 MHz. Thus, this example demonstrates that, if the system cannot correctly correlate return signals that arrive out of order, increasing the repetition rate from 500 kHz to 1 MHz (and thus improving the density of points of the system) may reduce the detection range of the system. Various techniques are used to mitigate the tradeoff between higher PRR and limited detection range. For example, multiple wavelengths can be used for detecting objects in different ranges. Optical and/or signal processing techniques are also used to correlate between transmitted and return light signals.

Various systems, apparatus, and methods described herein may be implemented using digital circuitry, or using one or more computers using well-known computer processors, memory units, storage devices, computer software, and other components. Typically, a computer includes a processor for executing instructions and one or more memories for storing instructions and data. A computer may also include, or be coupled to, one or more mass storage devices, such as one or more magnetic disks, internal hard disks and removable disks, magneto-optical disks, optical disks, etc.

Various systems, apparatus, and methods described herein may be implemented using computers operating in a client-server relationship. Typically, in such a system, the client computers are located remotely from the server computers and interact via a network. The client-server relationship may be defined and controlled by computer programs running on the respective client and server computers. Examples of client computers can include desktop computers, workstations, portable computers, cellular smartphones, tablets, or other types of computing devices.

Various systems, apparatus, and methods described herein may be implemented using a computer program product tangibly embodied in an information carrier, e.g., in a non-transitory machine-readable storage device, for execution by a programmable processor; and the method processes and steps described herein, including one or more of the steps of FIGS. 1-11, may be implemented using one or more computer programs that are executable by such a processor. A computer program is a set of computer program instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

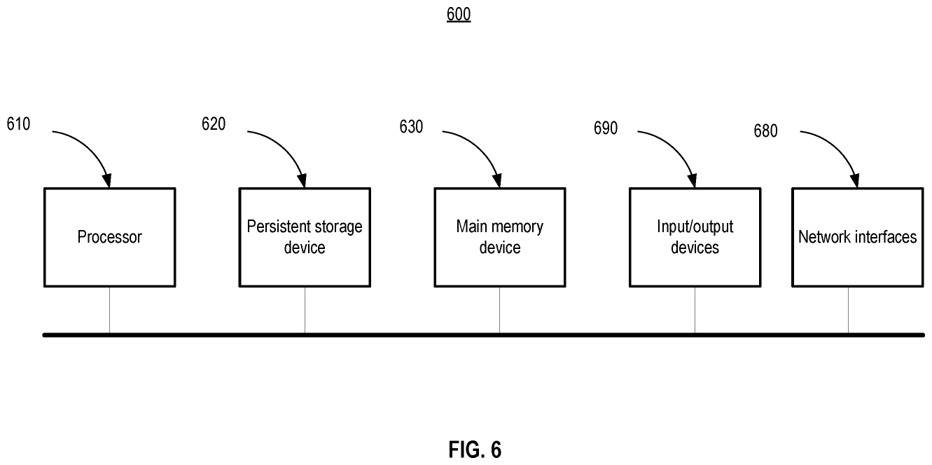

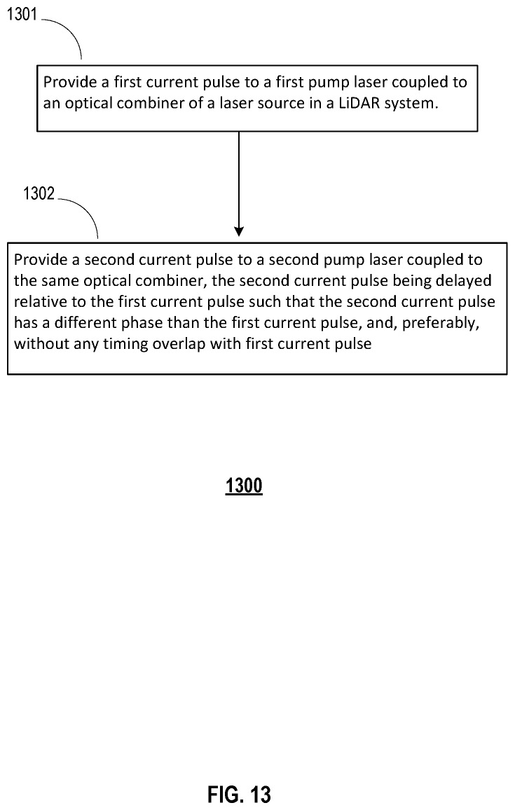

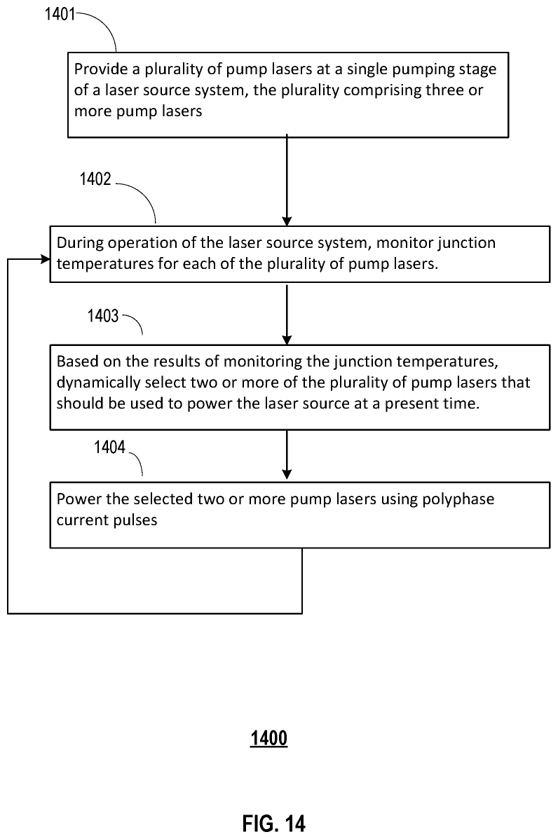

A high-level block diagram of an exemplary apparatus that may be used to implement systems, apparatus and methods described herein is illustrated in FIG. 6. Apparatus 600 comprises a processor 610 operatively coupled to a persistent storage device 620 and a main memory device 630. Processor 610 controls the overall operation of apparatus 600 by executing computer program instructions that define such operations. The computer program instructions may be stored in persistent storage device 620, or other computer-readable medium, and loaded into main memory device 630 when execution of the computer program instructions is desired. For example, processor 610 may be used to implement one or more components and systems described herein, such as control circuitry 350 (shown in FIG. 3), vehicle perception and planning system 220 (shown in FIG. 2), and vehicle control system 280 (shown in FIG. 2). Thus, any of the method steps of FIGS. 13-14, or methods steps otherwise described explicitly or implicitly herein can be defined by the computer program instructions stored in main memory device 630 and/or persistent storage device 620 and controlled by processor 610 executing the computer program instructions. For example, the computer program instructions can be implemented as computer executable code programmed by one skilled in the art to perform an algorithm defined by any of the method steps described herein. Accordingly, by executing the computer program instructions, the processor 610 executes an algorithm defined by the methods described herein. Apparatus 600 also includes one or more network interfaces 680 for communicating with other devices via a network. Apparatus 600 may also include one or more input/output devices 690 that enable user interaction with apparatus 600 (e.g., display, keyboard, mouse, speakers, buttons, etc.).

Processor 610 may include both general and special purpose microprocessors and may be the sole processor or one of multiple processors of apparatus 600. Processor 610 may comprise one or more central processing units (CPUs), and one or more graphics processing units (GPUs), which, for example, may work separately from and/or multi-task with one or more CPUs to accelerate processing, e.g., for various image processing applications described herein. Processor 610, persistent storage device 620, and/or main memory device 630 may include, be supplemented by, or incorporated in, one or more application-specific integrated circuits (ASICs) and/or one or more field programmable gate arrays (FPGAs).

Persistent storage device 620 and main memory device 630 each comprise a tangible non-transitory computer readable storage medium. Persistent storage device 620, and main memory device 630, may each include high-speed random access memory, such as dynamic random access memory (DRAM), static random access memory (SRAM), double data rate synchronous dynamic random access memory (DDR RAM), or other random access solid state memory devices, and may include non-volatile memory, such as one or more magnetic disk storage devices such as internal hard disks and removable disks, magneto-optical disk storage devices, optical disk storage devices, flash memory devices, semiconductor memory devices, such as erasable programmable read-only memory (EPROM), electrically erasable programmable read-only memory (EEPROM), compact disc read-only memory (CD-ROM), digital versatile disc read-only memory (DVD-ROM) disks, or other non-volatile solid state storage devices.

Input/output devices 690 may include peripherals, such as a printer, scanner, display screen, etc. For example, input/output devices 690 may include a display device such as a cathode ray tube (CRT), plasma or liquid crystal display (LCD) monitor for displaying information to a user, a keyboard, and a pointing device such as a mouse or a trackball by which the user can provide input to apparatus 600.

Any or all of the functions of the systems and apparatuses discussed herein may be performed by processor 610, and/or incorporated in, an apparatus or a system such as LiDAR system 300. Further, LiDAR system 300 and/or apparatus 600 may utilize one or more neural networks or other deep-learning techniques performed by processor 610 or other systems or apparatuses discussed herein.

One skilled in the art will recognize that an implementation of an actual computer or computer system may have other structures and may contain other components as well, and that FIG. 6 is a high-level representation of some of the components of such a computer for illustrative purposes.

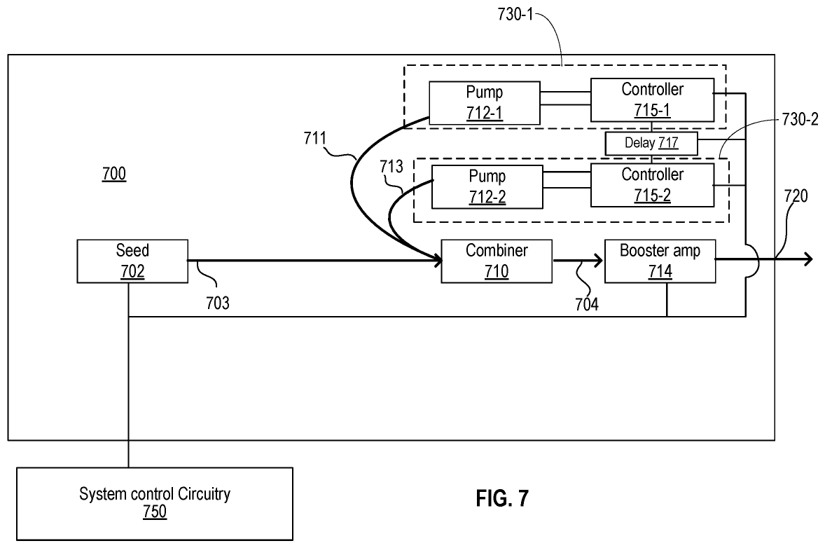

FIG. 7 is a block diagram is a block diagram illustrating an exemplary fiber-based laser source 700 having a seed laser and multiple pumps (e.g., laser diodes) operating at different phases at a single stage for pumping desired output optical power in accordance with one embodiment. Fiber-based laser source 700. In this embodiment, fiber-based laser source 700 comprises a seed laser 702 to generate light pulses of one or more wavelengths (e.g., 1550 nm), which are provided to a combiner 710 via an optical fiber 703. Laser source 700 further comprises pumps 712-1 and 712-2 which provide laser power (e.g., of a different wavelength, such as 980 nm) to combiner 710 via respective optical fibers 711 and 713.

Combiner 710 combines the light pulses provided by seed laser 702, pump 712-1, and pump 712-2 onto a single optical fiber 704. Combiner 710 can combine optical signals having the same wavelength or different wavelengths. One example of a combiner is a WDM. Combiner 710 provides pulses to a booster amplifier 714, which produces output light pulses via optical fiber 720. The booster amplifier 714 provides further amplification of the optical signals. The output light pulses can then be transmitted to transmitter 320 and/or steering mechanism 340 (shown in FIG. 3).

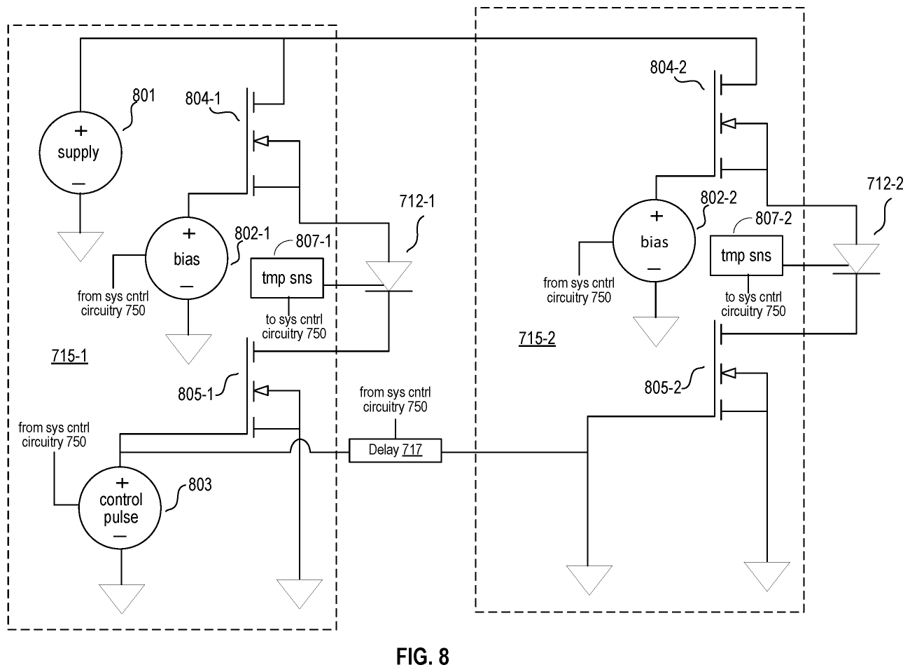

Laser source 700 further comprises controller 715-1, for controlling pump laser 712-1, and controller 715-2, for controlling pump laser 712-2. As will be described further in the context of FIG. 8, delay circuit 717 provides a delay (in one example, the delay is configurable) for a pulse control signal so that output pulses of pump lasers 712-1 and 712-2 can be offset relative to one another.

In the illustrated embodiment, pump laser 712-1 and controller 715-1 are provided on one chip 730-1. Similarly, pump laser 712-2 controller 715-2 are provided on another chip 730-2. However, those skilled in the art will appreciate that, in alternative embodiments, multiple pump lasers and corresponding control circuits could be provided on the same chip.

As shown, LiDAR system control circuitry 750 is coupled to seed laser 702, booster amp 714, controllers 715-1 and 715-2 and delay circuit 717. As those skilled in the art will appreciate, delay circuit 717 may be provided as part of LiDAR system control circuitry 750 to offset the phase of an electrical pulse provided to controller 715-1 relative to one provided to controller 715-2. It is shown separately from system control circuitry 750 in the diagram of FIG. 7 (and in FIGS. 8-10) for illustrative purposes.

In various embodiments, a variety of relationships between a triggering rate of seed laser 702 and control pulses provided by control circuits 715-1 and 715-2 may be used. In some embodiments, a seed laser triggering rate is different than the pulse rate of currents provided by the control circuits to trigger pump lasers 712-1 and 712-2. In some embodiments, a seed laser triggering rate is in the range of 5-500 kilohertz (kHz) and the pulse rate of signals triggering the pump lasers is in a range of 250-1500 kHz. In some embodiments, the sum of duty cycles of signals triggering the pump lasers is less than one.

It is understood that FIG. 7 illustrates one exemplary configuration of fiber-based laser source 700. Laser source 700 can have many other configurations using different combinations of one or more components shown in FIG. 7 and/or other components not shown in FIG. 7 (e.g., other components such as power supplies, lens, filters, splitters, combiners, etc.).

FIG. 8 illustrates further details of one embodiment of controllers 715-1 and 715-2 of FIG. 7 for controlling pump laser diodes 712-1 and 712-2. As illustrated in FIG. 8, controller 715-1 comprises voltage supply 801, regulator transistor 804-1, switching transistor 805-1, bias voltage 802-1, control pulse 803, and temperature sensing circuit 807-1. Controller 715-2 comprises regulator transistor 804-2, switching transistor 805-2, bias voltage 802-2 and temperature sensing circuit 807-2. In this embodiment, the illustrated transistors are NMOS transistors (n-channel metal oxide semiconductor field effect transistors). As those skilled in the art will appreciate, other types and arrangements of transistors can be used without departing from the spirit of the illustrated embodiment. In various embodiments, the relevant switching and/or regulating transistors are on or more of: an insulated gate field-effect transistor (FET), a metal-oxide semiconductor FET (MOSFET), a metal-semiconductor FET (MESFET), a fin field-effect transistor (FinFET), a gate-all-around FET (GAAFET), and a bipolar transistor. In various embodiments, the transistors may be one or more of a silicon-based transistor, a gallium arsenide (GaA)-based transistor, a silicon-carbide (SiC)-based transistor, or a gallium nitride (GaN)-based transistor.

As shown, supply voltage 801 is coupled to respective drains of transistors 804-1 and 804-2. Bias voltages 802-1 and 802-2 are coupled to respective gates of regulator transistors 804-1 and 804-2 to control the amplitude of the current pulses through the circuit and hence through pump laser diodes 712-1 and 712-2. System control circuitry 750 controls the value of the bias voltage provided by 802-1 and 802-2. Laser diode 712-1 is coupled between the source of transistor 804-1 and the drain of transistor 805-1. Similarly, laser diode 712-2 is coupled between the source of transistor is coupled between the source of transistor 804-2 and the drain of transistor 805-2.

In operation, a voltage pulse from control pulse 803 switches transistors 805-1 and 805-2 on and off, thereby generating current pulses through laser pump diodes 712-1 and 712-2. Delay circuit 717 delays the voltage pulses at transistor 805-2 relative to those at transistor 805-1, and therefore the current pulses at pump laser diode 712-2 are phase-delayed relative to those at pump laser diode 712-1.

In some embodiments, delay circuit 717 is programmable based on signals received from system control circuitry 750 such that the amount of delay provided by delay circuit 717 can be re-configured.

As will be described further in the context of FIG. 14, temperature sensing circuits 807-1 and 807-2 monitor the respective junction temperatures of respective pump laser diodes 712-1 and 712-2. The temperature sensing circuits provide temperature-dependent signals to system control circuitry 750. As explained in the context of FIG. 14, in embodiments with several pump lasers at one pumping stage, such temperature monitoring circuits can allow system control circuitry to dynamically adjust which pump lasers are in use to minimize heating of any one pump laser and thereby enhance pump laser lifetime.

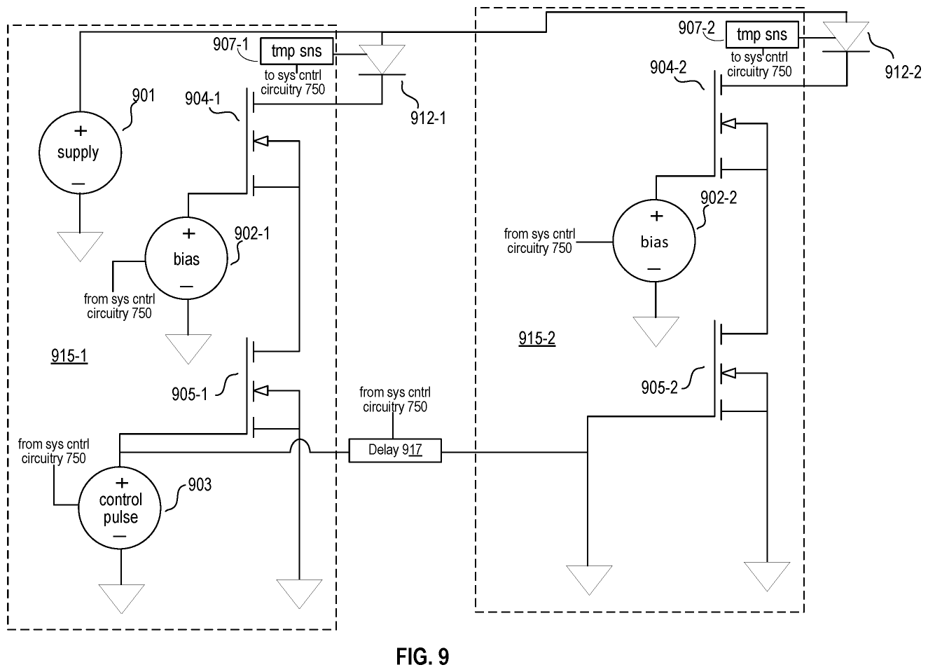

FIG. 9 illustrates an alternative embodiment to the embodiment shown in FIG. 8. In the FIG. 9 embodiment, controller circuits 915-1 and 915-2 each comprise transistors in a cascode arrangement.

Laser pump diode 912-1 is coupled between voltage supply 901 and the drain of regulator transistor 904-1. Similarly, laser pump diode 912-2 is coupled between voltage supply 901 and the drain of regulator transistor 904-2. Regulator transistor 904-1 and switching transistor 905-1 are coupled in a cascode arrangement with the source of regulator transistor 904-1 coupled to the drain of switching transistor 905-1. Regulator transistor 904-2 and switching transistor 905-2 are similarly coupled as shown. Control pulse 903 is coupled to the gate of switching transistor 905-1. A delay circuit 917 is coupled between control pulse 903 and the gate of switching transistor 905-2.

Operation of the embodiment of FIG. 9 proceeds similarly to the embodiment of FIG. 8. A voltage pulse from control pulse 903 switches transistors 905-1 and 905-2 on and off, thereby generating current pulses through laser pump diodes 912-1 and 912-2. Delay circuit 917 delays the voltage pulses at transistor 905-2 relative to those at transistor 905-1, and therefore the current pulses at pump laser diode 912-2 are phase-delayed relative to those at pump laser diode 912-1.

Bias voltage 902-1 provides a voltage to the gate of regulating transistor 904-1 that regulates the amplitudes of the current pulses through controller circuit 915-1, including through pump laser diode 912-1. Similarly, bias voltage 902-2 provides a voltage to the gate of gate of regulating transistor 904-2 that regulates the amplitudes of the current pulses through controller circuit 915-2, including through pump laser diode 912-2.

Temperature sensing circuit 907-1 monitors the junction temperature of pump laser diode 912-1 and provides temperature-dependent signals to system control circuitry 750. Similarly, temperature sensing circuit 907-2 monitors the junction temperature of pump laser diode 912-2 and provides temperature-dependent signals to system control circuitry 750.

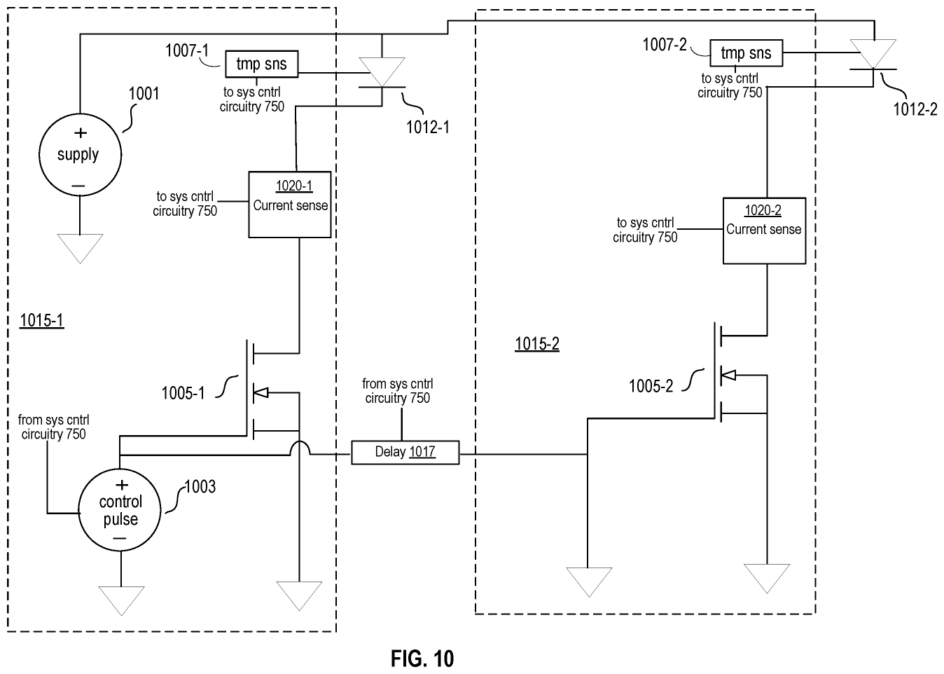

FIG. 10 shows another alternative embodiment to the embodiment of FIG. 8. In the embodiment of FIG. 10, the relevant controllers use current sensing circuits to determine an amplitude of a voltage pulse provided by a control pulse generator.

Specifically, laser pump diode 1012-1 is coupled between voltage supply 1001 and current sense circuit 1020-1. Similarly, laser pump diode 1012-2 is coupled between voltage supply 1001 and current sense circuit 1020-2. Current sense circuit 1020-1 is coupled to the drain of switching transistor 1005-1. Similarly, current sense circuit 1020-2 is coupled to the drain of switching transistor 1005-2. Control pulse 1003 is coupled to the gate of switching transistor 1005-1. A delay circuit 1017 is coupled between pulse 1003 and the gate of switching transistor 1005-2.

Operation of the embodiment of FIG. 10 proceeds as follows: A voltage pulse from control pulse 1003 switches transistors 1005-1 and 1005-2 on and off, thereby generating current pulses through laser pump diodes 1012-1 and 1012-2. Delay circuit 1017 delays the voltage pulses at transistor 1005-2 relative to those at transistor 1005-1, and therefore the current pulses at pump laser diode 1012-2 are phase-delayed relative to those at pump laser diode 1012-1.

Current sense circuit 1020-1 senses the current through control circuit 1015-1 (and hence through pump laser diode 1012-1) and provides a voltage signal to system control circuitry 750 (shown in FIG. 7). The voltage signal is responsive to (i.e., correlates with for measurement purposes) the current through control circuit 1015-1. Control circuitry 750 uses voltage output of current sense circuit 1020-1 to control the amplitude of the voltage pulse provided by control pulse 1003 so that the amplitude of the current pulses through circuit 1015-1 and pump laser diode 1012-1 are maintained at a desired level.

Similarly, current sense circuit 1020-2 senses the current through control circuit 1015-2 (and hence through pump laser diode 1012-2) and provides a voltage signal to system control circuitry 750 response to the current through control circuit 1015-2. Control circuitry 750 uses the output of current sense circuit 1020-2 to control the amplitude of the voltage pulse provided by control pulse 1003 so that the amplitudes of the current pulses through circuit 1015-2 and pump laser diode 1012-2 are maintained at a desired level.

Temperature sensing circuit 1007-1 monitors the junction temperature of pump laser diode 1012-1 and provides temperature-dependent signals to system control circuitry 750. Similarly, temperature sensing circuit 1007-2 monitors the junction temperature of pump laser diode 1012-2 and provides temperature-dependent signals to system control circuitry 750.

One skilled in the art will appreciate that there are various known ways to implement a current sense circuit such as current sense circuits 1020-1 and 1020-2. In a typical example, a current sense circuit comprises op-amp circuitry coupled to a sensing resistor though which the sensed current flows.

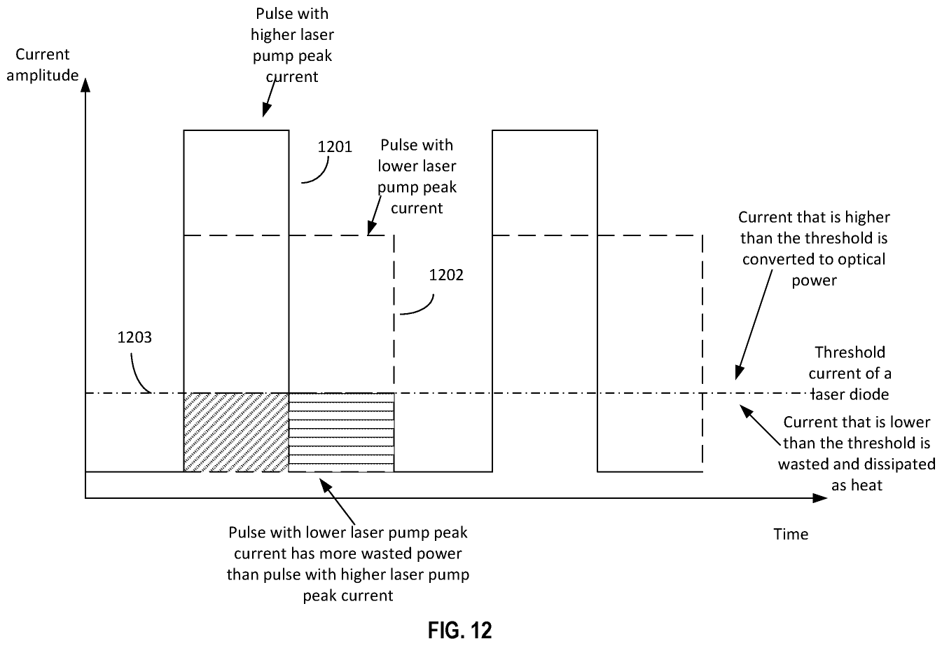

The examples in FIGS. 7-10 show two pump lasers and respective controllers at a single pumping stage of a laser source. In operation, the pump lasers output optical pulses in an alternating fashion in response to the two controllers providing current pulses in an alternating fashion. As will be explained further in the context of FIG. 12, this arrangement allows use of shorter, higher amplitude current pulses being applied to the pump laser diodes, thereby allowing a higher percentage of each current pulse to be above the pump laser's threshold current. Therefore, a greater percentage of electrical power is converted to optical power and the efficiency and lifespan of the system is improved.

However, the principles of the examples in FIGS. 7-10 are readily applicable to embodiments with a greater number of pump lasers at a single pumping stage (e.g., 3, 4, 5, 6, or more pump lasers at a single pumping stage). Moreover, although the embodiment of FIG. 7 shows a single pumping stage, the principles of embodiments of the present disclosure apply to laser sources with multiple pumping stages. In such alternatives one or more pumping stages may each have a plurality of pump lasers operating in polyphase fashion with respect to each other (i.e., two or more pump lasers with pulses at different phases).

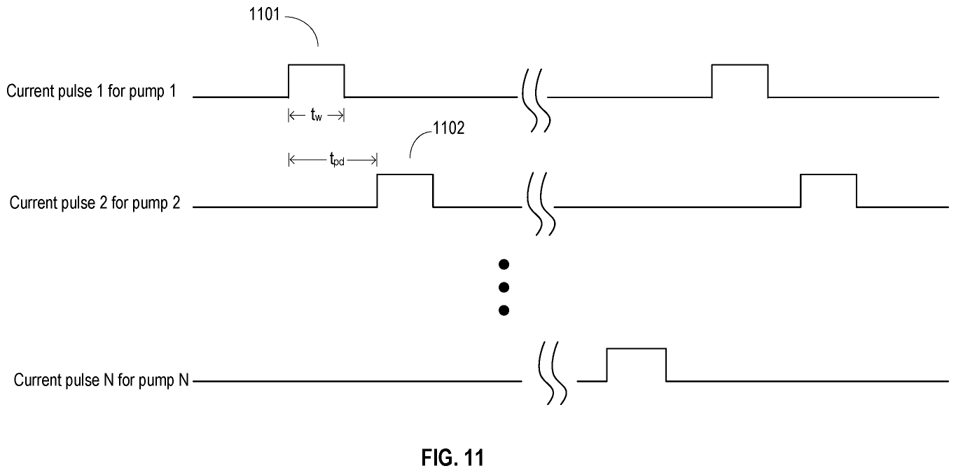

FIG. 11 is a timing diagram illustrating a plurality of current pulses at different phases for powering respective pump lasers. As shown, current pulse 1101 is generated to power a first pump laser and a second current pulse 1102 is generated to power a second pump laser. In total, N different current pulses can be generated to power N different pump lasers.

As illustrated, the current pulses have a width (i.e., a time length) of t_{w}. Current pulses 1101 and 1102 have a phase different of t_{pd}. In one embodiment, the phase difference between pulses for powering different pumps is equal to or greater than the pulse width. In some embodiments, when several different current pulses are used to power several different pump lasers at a same pumping stage, the pulses can be staggered such that the larger the number of pulses and corresponding pump lasers are used at a given pumping stage, the smaller the duty cycle is for each pulse.

Furthermore, in some embodiments, the phase delay between successive pulses controlling successive pump lasers is greater than the pulse width such that successive pulses controlling successive pump lasers are non-overlapping in timing and the sum of the duty cycles of all the control pulses is less than one.

In some embodiments only two of a plurality of pumps are powered using different phase current pulses. In other embodiments, more than two or all of a plurality of pumps are powered using different phase current pulses.

In some embodiments, a plurality of pump lasers are provided and, during operation, a junction temperature of the pump lasers is monitored. In some embodiments, the number of pump lasers receiving activating control signals is determined dynamically based on a result of the junction temperature monitoring.

FIG. 12 is a timing diagram comparing a higher peak current of a pulse powering a laser pump with a lower peak current of a pulse powering the laser pump to illustrate certain advantages of embodiments of the present invention. In this example, the laser pump has a threshold current 1203. Current provided below the threshold current is not converted into optical power. Only current at or above the threshold current is converted to optical power. Two pulses, 1201 and 1202 are shown for comparison. Pulse 1201 has a narrower width and higher amplitude than pulse 1202. As a result, a lower percentage of the total area under pulse 1201 is under threshold current 1203 than is the case for pulse 1202. Therefore, pulse 1201 results in less wasted power (greater efficiency) than pulse 1202. Embodiments of the present invention facilitate using higher amplitude, narrower width pulses than the prior art, thereby increasing efficiency and potentially system lifetime relative to the prior art. By arranging multiple pump lasers at a single pumping stage, current pulses can be alternated to power the plurality of pump laser for shorter time periods at higher amplitudes, thus avoiding constant lower amplitude current (or at least avoiding wider low amplitude pulses) which would have a higher percentage of wasted power below the threshold current.

FIG. 13 is a flow diagram illustrating a method 1300 in accordance with one embodiment of the invention. Step 1301 provides a first current pulse to a first pump laser. The first pump laser is optically coupled to a first optical combiner (e.g., a wavelength division multiplexor or another optical combiner) of a laser source in a LiDAR system. Step 1302 provides a second current pulse to a second pump laser. The second pump laser is optically coupled to the same optical combiner as the first pump laser. In other words, it is part of the same pumping stage. The second current pulse is delayed relative to the first current pulse such that it has a different phase. Preferably, the time of the phase difference between the first and second pulse is enough that there is no timing overlap between the first pulse powering the first pump laser and the second pulse power the second pump laser. In one embodiment, the pulse widths are less than the phase delay such that the sum of the duty cycles of the two pulses is less than one.

FIG. 14 illustrates method 1400 in accordance with one embodiment of the invention. In some embodiments, three or more pump lasers (e.g., laser diodes) are used at a single pumping stage of a laser source system. This allows some redundancy and the possibility of improved system lifetime. In one embodiment, a junction temperature of the pump lasers is monitored during operation of the laser source system (e.g., by temperature monitoring circuits such as those shown in FIGS. 8-10) and, if a junction temperature of one of the pump lasers exceeds a pre-determined amount, then only others of the three or more pump lasers are used.

Step 1401 provides a plurality of pump lasers at a single pumping stage of a laser source system. The plurality includes at least three or more pump lasers so that at least two pump lasers can operate in polyphase fashion even if one of the pumps is not presently used due to excessive junction temperature.

Step 1402 monitors junction temperatures for each of the plurality of pump lasers. Step 1403 uses the results of step 1402's temperature monitoring to select two or more of the plurality of pump laser to be used for powering the laser source system at a present time. If one of the plurality of pump lasers has a junction temperature that is either above or too close to being above a pre-determined junction temperature, then others of the plurality of pump lasers can be selected. Step 1404 powers the selected two or more pump lasers using polyphase current pulses.

Steps 1402, 1403, and 1404 continue (either periodically or continuously) during operation of the laser source system so that the pump laser selection can be dynamically updated based on changes in results of junction temperature monitoring.

In one embodiment, circuitry for implementing the processing of method 1400 is provided as part of system control circuitry such as system control circuitry 750. One skilled in the art that the corresponding logic can be readily implemented in software, hardware, firmware, and/or a combination thereof.

In various embodiments of the present invention, a pump diode is driven in a pulsed manner instead of constant current. The pulse current amplitude can be constant. The pulse current amplitude can be up to the maximum allowed by the safe operation of pump diode. For a given amplitude, the average current of a pump diode can be controlled by pulse width. The average current is determined by the designated fiber laser power. Total number of pump diodes is determined by cost, size, and target lifetime.

In various embodiments of the present invention, all pump diodes can be turned on in an alternating way, e.g., by using polyphase driving. The seed laser trigger can be used as time base to turn on pump laser. The seed trigger rate can be constant or pulse position keying (PPK). A certain delay (in some embodiments, a programmable delay) can be inserted between seed triggering and switching on the pump diode.

Some of the advantage of the embodiments of the present invention are as follows. First, the design is using generic power devices. It can be cost effective and has large components selection. Second, the pulsed current can improve driving efficiency over constant driving current since laser diode has a significant threshold. Third, all pump diodes turn on alternatively. As a result, it will reduce power consumption over each individual device and lower the junction temperature of each device in operation which is critical to extend each individual device lifetime.

The foregoing specification is to be understood as being in every respect illustrative and exemplary, but not restrictive, and the scope of the invention disclosed herein is not to be determined from the specification, but rather from the claims as interpreted according to the full breadth permitted by the patent laws. It is to be understood that the embodiments shown and described herein are only illustrative of the principles of the present invention and that various modifications may be implemented by those skilled in the art without departing from the scope and spirit of the invention. Those skilled in the art could implement various other feature combinations without departing from the scope and spirit of the invention.

1-55. (canceled)

56. An electronic device for facilitating a polyphase control of a plurality of laser pumps used in a laser source, the device comprising:
one or more power supplies operative to provide power to the plurality of laser pumps;
a plurality of pump controllers electrically and respectively coupled to the plurality of laser pumps, each of the plurality of pump controllers being operative to control an operational status of a respective laser pump of the plurality of laser pumps; and
one or more pump control signal generators electrically coupled to the plurality of pump controllers, the one or more pump control signal generators being operative to generate a plurality of control signals to switch switches in the respective pump controllers such that at least two of the plurality of laser pumps are provided with pulse currents in an alternating manner.

57. The device of claim 56, wherein at least one of the plurality of pump controllers comprises a transistor-based switch electrically coupled to a respective laser pump of the plurality of laser pumps.

58. The device of claim 57, wherein the transistor-based switch comprises one or more of an insulated gate field-effect transistor (FET), a metal-oxide semiconductor FET (MOSFET), a metal-semiconductor FET (MESFET), a fin field-effect transistor (FinFET), a gate-all-around FET (GAAFET), and a bipolar transistor.

59. The device of claim 57, wherein the transistor-based switch comprises at least one of a Silicon-based transistor, a Gallium Arsenide (GaA)-based transistor, a Silicon-Carbide (SiC)-based transistor, or a Gallium Nitride (GaN)-based transistor.

60. The device of claim 57, wherein the transistor-based switch comprises a first transistor having a first terminal and a second terminal,
wherein the first terminal of the first transistor is coupled to a pump control signal generator of the one or more pump control signal generators to receive a control signal of the plurality of control signals.

61. The device of claim 60, wherein the second terminal of the first transistor is coupled to the laser pump.

62. The device of claim 61, wherein the second terminal of the first transistor is further coupled to a current sensing circuit, or
wherein the first transistor facilitates current sensing by using an on-resistance of the first transistor.

63. The device of claim 60, wherein the transistor-based switch further comprises a second transistor having a first terminal, a second terminal, and a third terminal, the second transistor being operative to facilitate current regulating,
wherein the first terminal of the second transistor is coupled to a bias power supply.

64. The device of claim 63, wherein the bias power supply is configured to cause the laser pump to have multiple levels of peak current, one of the multiple levels of peak current corresponding to a maximum permitted peak current that does not cause irreversible damage to the laser pump.

65. The device of claim 63, wherein:
the second terminal of the second transistor is coupled to the laser pump, and
the third terminal of the second transistor is coupled to at least one of the one or more power supplies.

66. The device of claim 63, wherein:
the second terminal of the second transistor is coupled to the second terminal of the first transistor such that the first transistor and the second transistor form a cascode configuration; and
the third terminal of the second transistor is coupled to the laser pump.

67. The device of claim 57, wherein the transistor-based switch comprises a plurality of transistors formed in a cascode configuration.

68. The device of claim 57, wherein the transistor-based switch comprises a current switch that is operative to turn on or turn off to control a current flowing through the laser pump.

69. The device of claim 57, wherein the transistor-based switch facilitates current switching at a speed on the order of nano-seconds or sub nano-seconds.

70. The device of claim 57, further comprising a current sensing circuit operative to sense current of the laser pump.

71. The device of claim 56, wherein the plurality of laser pumps comprises laser diodes.

72. The device of claim 56, wherein the plurality of control signals comprises a plurality of electrical pulses, each of the plurality of electrical pulses switches a switch in a respective pump controller such that the respective laser pump is provided with one or more pulse currents.

73. The device of claim 72, wherein the plurality of control signals are non-overlapping in timing such that only one laser pump of the plurality of laser pumps is provided with a pulse current at a time.

74. The device of claim 72, wherein the plurality of control signals comprises a sequence of electrical pulses arranged according to time positions of the electrical pulses, and wherein the plurality of laser pumps are provided with respective pulse currents in sequence according to the sequence of electrical pulses.

75. The device of claim 72, wherein at least two of the plurality of pulse control signals overlap in timing.

76. The device of claim 72, wherein at least one of a triggering rate, a duty ratio, and a pulse duration of the plurality of electrical pulses is determined based on a seed laser triggering rate or the seed laser triggering signal modulation.

77. The device of claim 76, wherein the seed laser triggering rate is different from a rate of pulse currents provided to the laser pump or a rate of the plurality of electrical pulses that switch transistors in the pump controllers.

78. The device of claim 77, wherein the seed laser triggering rate has any value within a range of 5 k-500 k, and wherein the rate of the pulse currents provided to the laser pump or the rate of the plurality of electrical pulses that switch transistors in the pump controllers has any value within a range of 250 k-1500 k.

79. The device of claim 72, wherein a sum of duty ratios of the plurality of electrical pulses for triggering respective pump controllers is less than one.

80. The device of claim 56, further comprising:
one or more seed lasers; and
one or more delay circuits coupled to the one or more seed lasers and the plurality of pump controllers, each of the delay circuit being operative to cause a delay between triggering of a corresponding seed laser and switching a transistor of a corresponding pump controller.

81. The device of claim 80, wherein a phase delay or a time delay between triggering of a corresponding seed laser and switching of a switch of a corresponding pump controller is programmable.

82. The device of claim 80, wherein the one or more seed lasers are operative to generate seed laser pulses; and wherein the plurality of control signals comprises a plurality of electrical pulses for switching transistors in the plurality of pump controllers.

83. The device of claim 56, wherein the one or more pump control signal generators are configured to generate the plurality of control signals such that only one of the plurality of laser pumps is provided with a pulse current within any single laser firing cycle of the laser source.

84. The device of claim 56, wherein the one or more pump control signal generators are configured to generate the plurality of control signals such that in at least two different laser firing cycles, different laser pumps of the plurality of laser pumps are turned on.

85. The device of claim 56, wherein the one or more pump control signal generators are configured to generate the plurality of control signals such that pulsed currents provided to different laser pumps of the plurality of laser pumps are non-overlapping in timing.

86. The device of claim 56, further comprising:
one or more current sensing circuits operative to sense the pulse currents;
digital sampling circuits coupled to the one or more current sensing circuits, the digital sampling circuits being operative to sample the sensed pulse currents; and
feedback circuits coupled to the digital sampling circuits, the feedback circuits being operative to provide one or more adjustment signals to the one or more pump control signal generators to adjust the plurality of control signals.

87. A laser source comprising an electronic device of claim 56.

88. The laser source of claim 87, further comprising:
one or more seed lasers operative to provide seed laser light;
one or more combiners operative to combine seed laser light with pump laser light provided by the one or more laser pumps; and
one or more optical amplifiers operative to receive the combined light and amplify the seed laser light using the pump laser light.

89. A light ranging and detection (LiDAR) system comprising a laser source having an electronic device of claim 56.

90. A vehicle comprising a light ranging and detection (LiDAR) system of claim 89.

91. A method for facilitating a polyphase control of a plurality of laser pumps used in a laser source, comprising:
providing, by one or more power supplies, power to the plurality of laser pumps;
controlling, by each of a plurality of pump controllers electrically and respectively coupled to the plurality of laser pumps, an operational status of a respective laser pump of the plurality of laser pumps; and
generating, by one or more pump control signal generators electrically coupled to the plurality of pump control devices, a plurality of control signals to switch respective transistors of respective pump controllers such that at least two of the plurality of laser pumps are provided with pulse currents in an alternating manner.

92. The method of claim 91 further comprising:
monitoring junction temperatures of the plurality of laser pumps
determining the number of laser pumps that should be provided with pulse currents based on a junction temperature monitoring result; and
dynamically adjusting the plurality of control signals such that the determined number of the plurality of laser pumps are provided with pulse currents in an alternating manner.

93. The method of claim 92, wherein:
the junction temperature monitoring result is compared with a threshold temperature;
if the junction temperature monitoring result is greater than the threshold temperature, the number of the laser pumps that should be provided with pulse currents is increased; and
if the junction the junction temperature monitoring result is no greater than the threshold temperature, the number of the laser pumps that should be provided with pulse currents is maintained or decreased.

94. The method of claim 92, wherein:
the junction temperature monitoring result is compared with a threshold temperature;
if the junction temperature monitoring result is greater than the threshold temperature, a laser pump for which the junction temperature monitoring result is greater than the threshold is either paused or controlled to have a lower duty cycle.
